(19) United States
(12) Patent Application Publication
(10) Pub. No.: US 2008/0254256 A1
(43) Pub. Date: Oct. 16, 2008

(54) Heat-resistant light-shading film and production method thereof, and diaphragm or light intensity adjusting device using the same

(75) Inventors: Yoshiyuki Abe, Ichikawa-shi (JP); Katsushi Ono, Ichikawa-shi (JP); Yukio Tsukakoshi, Ichikawa-shi (JP)

Correspondence Address: Edwards Angell Palmer & Dodge LLP, P.O. Box 55874, Boston, MA, 02205, US

(73) Assignee: Sumitomo Meta Mining Co., Ltd., Tokyo (JP)

(21) Appl. No.: 12/010,734

(22) Filed: Jan. 29, 2008

(30) Foreign Application Priority Data
Apr. 10, 2007 (JP) 2007-103138
Aug. 10, 2007 (JP) 2007-210051

(51) Int. Cl. B32B 33/00; B32B 15/08; C23C 14/14

(52) U.S. Cl. 428/141; 428/336; 204/192.14

(57) ABSTRACT

A heat-resistant light-shading film having high light shading capacity, high heat resistance, high sliding characteristics, low surface gloss and high electroconductivity, and useful for optical device parts such as shutter blades or diaphragm blades for diaphragm blades of lens shutter and the like for digital cameras and digital video cameras and diaphragm blades of light intensity adjusting device for projectors, and a method for producing the same.

The heat-resistant light-shading film is a film comprising a resin film substrate (A) having a heat resistance of 155° C. or higher and a light-shading layer (B) of crystalline metal carbide film (MeC) formed on one side or both sides of the resin film substrate (A), characterized in that the light-shading layer (B) has a thickness of 100 nm or more and a surface roughness of 0.1 to 2.1 μm (arithmetic average height Ra), and content of carbon element (C) in the metal carbide film (MeC) is 0.3 or more in atomic number ratio to the total metal elements (Me).

### BACKGROUND OF THE INVENTION

1. Field of the Invention

The present invention relates to a heat-resistant light-shading film and method for producing the film, and diaphragm or light intensity adjusting device using the film, in more detail, a heat-resistant light-shading film having high light shading capacity, high heat resistance, high sliding characteristics, low surface gloss and high electroconductivity, which are used as optical device parts, e.g. shutter blade or diaphragm blades for diaphragm or lens shutter for digital cameras and digital video cameras and the like, fixed diaphragm in lens unit for in-vehicle monitors, and diaphragm blades of light intensity adjusting device for projectors; method for producing the film; and diaphragm or light intensity adjusting device using the film.

2. Description of the Prior Art

Recently, shutter blades or diaphragm blades for cameras have been required to be lighter and have higher sliding characteristics as shutter speed increases, because they are subjected to starting/stopping cycles in a very short time. In addition, they are basically required to have light shading capacity, because they cover photosensitive materials such as films, or front surfaces of imaging devices such as CCDs, to shade light. Moreover, they are required to have sufficient lubricity for smooth motion of blades for which they are used, because a plurality of blades work while overlapping each other in optical devices. Still more, they are required to have a low surface reflectance to prevent leakage of light between blades. Still more, they are required to be resistant to heat, because the inside of cameras may become high temperature depending on service environments.

On the other hand, light-shading films for light intensity adjusting diaphragm blades for liquid-crystal projectors as projectors for presentation or image viewing devices for home theaters or the like are required to have characteristics similar to those for digital cameras and digital video cameras, or in particular, as for higher heat resistance, they are required to have a characteristics over the camera.

The commercial light-shading films described above are generally supported by a plastic film substrate such as polyethylene terephthalate (PET) film or thin metallic plate of SUS, SK material, Al or the like. When a light-shading film supported by a metallic substrate is used as a shutter blade or diaphragm blade in a camera, the metallic plates will graze with each other when the blades are opened and closed to generate large noise. In addition, in a liquid-crystal projector, the blade is required to move at a high speed to reduce brightness changes when images are changed, with the result that the blades will graze with each other to repeatedly generate noise. In addition, to operate the blades at a lower speed to reduce noise caused a problem to produce unstable images, because light intensity adjustment may not sufficiently follow changed images.

From the viewpoint of the above problems and for reducing the weight, recently, light-shading films have been mainly supported by a plastic film substrate, in order to solve. Moreover, they are required to be electroconductive to reduce evolution of dust. Therefore, it is accepted that they are required to satisfy the characteristics of high light shading capacity, high heat resistance, low surface gloss, high sliding characteristics, high electroconductivity and low dust evolution. Various film materials and structures have been proposed from the past to satisfy the characteristics which light-shading films are required to have.

For example, Patent Document 1 discloses a light-shading film with a resin film such as polyethylene terephthalate (PET) film, which is impregnated with fine, black, electroconductive particles of carbon black, titanium black or the like to provide the film with light-shading capacity and electroconductivity, and is matting treated at least on one side to decrease surface gloss, wherein the fine black particles work to absorb light emitted from a light source such as lamp, from the viewpoint of high light-shading capacity, low surface gloss and high electroconductivity.

Patent Document 2 discloses a light-shading film with a resin film coated with a thermosetting resin layer containing a black pigment such as carbon black, having light-shading capacity and electroconductivity, lubricant and delustering agent to have light-shading capacity, electroconductivity, lubricity and low surface gloss.

Patent Document 3 discloses a light-shading material coated with a hard carbon film on a surface of metallic blade material of aluminum alloy or the like.

Patent Document 4 discloses a light-shading blade structure and reinforced with a prepreg sheet of thermosetting resin containing carbon fibers on each side of a plastic, to improve blade rigidity.

Light-shading films have been widely used as light-shading blade materials for optical devices such as digital cameras, digital video cameras and liquid-crystal projectors. Recently, liquid-crystal projectors have been required to produce high-quality, bright images of high contrast in bright atmospheres, e.g., those in living rooms. Therefore, a lamp light source produces high output by brighter images, which tends to increase temperature in a diaphragm device for light intensity adjustment. Light-shading films for light intensity adjustment, when irradiated with light of high output, are placed in atmospheres in which they tend to thermally deform.

Light-shading films with a substrate of, for example, polyethylene terephthalate (PET) have been widely used because of their low specific gravity. However, when a lamp light source becomes a high output, polyethylene terephthalate (PET) has a low thermal deformation temperature and low mechanical strength such as tensile modulus, with the result that light-shading blades of polyethylene terephthalate may be deformed by vibrations and shocks and the like generating in the running or braking period as output of light sources.

In addition, light-shading films are matting-treated by sand blasting method in order to exert low surface gloss and high sliding characteristics. This treatment brings another effect of improving image visibility by scattering incident light and decreasing surface gloss. This treatment is considered to prevent deterioration of sliding characteristics, because of controlled growth of contacting area between the light-shading films even when they come into contact with each other.

In digital cameras, digital video cameras and liquid-crystal projectors, since a plurality of light-shading films are used and are adjacent inevitably as shutter blades or diaphragm blades and work while overlapping each other, light-shading films which use an organic component light-shading material, lubricant and delustering agent have been subjected to severer service conditions such as temperature or humidity, exposed in digital cameras, digital video cameras and liquid-crystal projectors. Fixed diaphragm used for lens unit of in-vehicle monitors is used even at a high temperature of 100 to 155° C. In liquid-crystal projectors, in particular, inside temperature of their devices (light intensity adjusting devices, diaphragm devices) is increasing to near 200° C., due to output of high lamp light sources, accompanied by images of recent higher brightness, increases, as discussed above. In these severe environments, the conventional light-shading films described above showed unfavorable phenomena in durability such as, e.g., deformation or discoloration, and caused problems in practical use.

Light-shading films, when used at high temperature environment of 155° C. or higher, will be greatly deformed by heat, even when they have a fine concavity and convexity structure on the surface, with the result that they can no longer work at a high speed when they come into contact with each other, and have deteriorated sliding characteristics and surface gloss because they are grazing with each other more frequently irregularly. As a result, digital cameras, digital video cameras or liquid-crystal projectors, may no longer exhibit their intended functions.

In addition, matting treatment of a plastic film of a substrate forms fine concavity and convexity on a plastic film substrate to bring effects of improving adhesion between the substrate and coated film just over the substrate and reducing surface gloss. In sand blasting, however, film surface roughness depends on material and particle size of a shot material and discharge pressure and the like. A shot material of large particle size may be removed from the film surface by a cleaning method such as water washing or flushing. A shot material of fine particles smaller than 1 μm, on the other hand, cannot be completely removed, and the particles remain on the surface in no small quantity, even it is washed. The remaining shot material causes peel-off of the film at high temperature circumstances to which the light-shading film is exposed, and causes a peel-off of the shot material from the film due to difference of a thermal stress created by different thermal expansion coefficient between the shot material and film such as light-shading film of metal alloy formed on film. These troubles can have adverse effects on the surrounding parts, and generate a problem that the intended functions cannot be exhibited.

### Patent Documents

[Patent Document 1]: JP-A-1-120503

[Patent Document 2]: JP-A-4-9802

[Patent Document 3]: JP-A-2-116837

[Patent Document 4]: JP-A-2000-75353

### SUMMARY OF THE INVENTION

Thus, an object of the present invention is, in a light-shading film with a substrate film having a finely concavity and convexity structure on the surface of a substrate film, used as light intensity adjusting blades for liquid-crystal projectors, which are exposed to high temperature, or shutter blades and fixed diaphragm for digital cameras, which are exposed to high temperature in the processing step, to provide a heat-resistant light-shading film having high electroconductivity showing little deterioration of sliding and surface gloss characteristics, high durability making the film resistant to deformation and discoloration, and with no peel-off of the film and no drop-off of the shot material.

The inventors of the present invention have found, after having studied to solve the above-described problems involved in the conventional techniques, that a heat-resistant light-shading film showing little deformation, keeping characteristics (high light-shading capacity, low surface gloss, high sliding characteristics, color and low reflectance) in high temperature environments of 155° C. or higher, and around 200° C. depending on type of the substrate, and useful for diaphragm members for digital cameras, digital video cameras, liquid-crystal projectors and so forth, can be obtained by using a heat-resistant resin film (A) having heat resistance of 155° C. or higher as a substrate as a resin film having a fine concavity and convexity on the surface, and forming a light-shading layer (B), which is a crystalline metal carbide layer (sometimes described as MeC in specification) having a specified thickness, by sputtering method while surface temperature of the resin film substrate (A) is maintained at 155° C., and accomplished the present invention.

Namely, according to the first invention of the present invention, provided is a heat-resistant light-shading film comprising a resin film substrate (A) having a heat resistance of 155° C. or higher and a light-shading layer (B) of crystalline metal carbide layer (MeC) formed on one side or both sides of the resin film substrate (A), characterized in that the light-shading layer (B) has a thickness of 100 nm or more, a surface roughness of 0.1 to 2.1 μm (arithmetic average height Ra), and a content of carbon element (C) in the metal carbide layer (MeC) of 0.3 or more in atomic number ratio to the total metal elements (Me).

According to the second invention of the present invention, provided is the heat-resistant light-shading film according to the first invention, characterized in that the resin film (A) is composed of at least one kind of material selected from polyethylene naphthalate, polyimide, aramid, polyphenylene sulfide or polyether sulfone.

According to the third invention of the present invention, provided is the heat-resistant light-shading film according to the first or the second invention, characterized in that heat resistance of the resin film substrate (A) is 200° C. or higher.

According to the forth invention of the present invention, provided is the heat-resistant light-shading film according to any one of the first to the third inventions, characterized in that thickness of the resin film substrate (A) is 5 to 200 μm.

According to the fifth invention of the present invention, provided is the heat-resistant light-shading film according to any one of the first to the forth inventions, characterized in that surface roughness of the resin film substrate (A) is 0.2 to 2.2 μm (arithmetic average height Ra).

According to the sixth invention of the present invention, provided is the heat-resistant light-shading film according to any one of the first to the fifth inventions, characterized in that thickness of the light-shading layer (B) is 110 to 550 nm.

According to the seventh invention of the present invention, provided is the heat-resistant light-shading film according to any one of the first to the sixth inventions, characterized in that the metal carbide layer (MeC) comprises, as a main component, at least one kind of material selected from silicon carbide, titanium carbide, aluminum carbide, niobium carbide, tungsten carbide, molybdenum carbide, vanadium carbide, tantalum carbide, zirconium carbide or hafnium carbide.

According to the eighth invention of the present invention, provided is the heat-resistant light-shading film according to any one of the first to the seventh inventions, characterized in that carbon element (C) in the metal carbide layer (MeC) is 0.5 or more in atomic number ratio (C/Me) to the total metal elements (Me).

According to the ninth invention of the present invention, provided is the heat-resistant light-shading film according to any one of the first to the eighth inventions, characterized in that content of oxygen (O) in the metal carbide layer (MeC) is 0.5 or less in atomic number ratio of oxygen element (O) to the total metal elements (Me).

According to the tenth invention of the present invention, provided is the heat-resistant light-shading film according to any one of the first to the ninth inventions, characterized in that reflectance of the light-shading layer (B) for the light in a wavelength range from 380 to 780 nm is 10% or less.

According to the eleventh invention of the present invention, provided is the heat-resistant light-shading film according to any one of the first to the tenth inventions, characterized in that optical density as an index of light-shading capacity is 4 or more in a wavelength range from 380 to 780 nm.

According to the twelfth invention of the present invention, provided is the heat-resistant light-shading film according to any one of the first to the eleventh inventions, characterized in that metal carbide layers (MeC) having the same structure and thickness are formed on the both sides of the resin film substrate (A).

According to the thirteenth invention of the present invention, provided is a method for producing a heat-resistant light-shading film comprising a resin film substrate (A) having heat resistance of 155° C. or higher and a metal carbide layer (MeC) as a light-shading layer (B) formed on one side or both sides of the resin film substrate (A) according to the first to the twelfth inventions, characterized by comprising steps for supplying the resin film substrate (A) having a surface roughness of 0.2 to 2.2 μm (arithmetic average height Ra) to a sputtering unit; and for forming a crystalline metal carbide layer (MeC) having a thickness of 100 nm or more, a surface roughness of 0.1 to 2.1 μm (arithmetic average height Ra), and a content of carbon element (C) in the metal carbide layer (MeC) of 0.3 or more in atomic number ratio (C/Me) to the total metal elements (Me), on said resin film substrate (A) by the sputtering method using a metal carbide target in an inert gas atmosphere.

According to the fourteenth invention of the present invention, provided is the method for producing the heat-resistant light-shading film according to the thirteenth invention, characterized by comprising steps for supplying further a heat-resistant light-shading film with a metal carbide layer (MeC) formed thereon to a sputtering unit; and forming a metal carbide layer (MeC) on the other side of the resin film substrate (A) on which the metal carbide layer (MeC) has not been formed, by the sputtering method.

According to the fifteenth invention of the present invention, provided is the method for producing the heat-resistant light-shading film according to the thirteenth or the fourteenth invention, characterized in that sputtering gas pressure in the period of forming the light-shading layer (B) is 0.2 to 1.0 Pa.

According to the sixteenth invention of the present invention, provided is the method for producing the heat-resistant light-shading film according to any one of the thirteenth to the fifteenth inventions, characterized in that surface temperature of the resin film substrate (A) in the period of forming the light-shading layer (B) is 180° C. or higher.

According to the seventeenth invention of the present invention, provided is the method for producing the heat-resistant light-shading film according to any one of the thirteenth to the sixteenth inventions, characterized by comprising steps for setting the resin film substrate (A) in a rolled form in a film transfer section of the sputtering unit; and for forming a layer by the sputtering method while the resin film substrate (A) is running from a wind-off section to a take-up section.

In addition, according to the eighteenth invention of the present invention, provided is the method for producing the heat-resistant light-shading film according to any one of the thirteenth to the seventeenth inventions, characterized by comprising steps for setting the resin film substrate (A) in a rolled form in a film transfer section of the sputtering unit; and for forming a layer by the sputtering method while the resin film substrate (A) is running from a wind-off section to a take-up section, wherein the layer is formed while the resin film substrate (A) is not cooled and is formed in a floating state in a film-forming chamber.

In addition, according to the nineteenth invention of the present invention, provided is a diaphragm having superior heat resistance obtained by processing the heat-resistant light-shading film according to any one of the first to the twelfth inventions.

In addition, according to the twentieth invention of the present invention, provided is a light intensity adjusting device using the heat-resistant light-shading film according to any one of the first to the twelfth inventions.

Since, in the heat-resistant light-shading film of the present invention, a metal carbide layer having a specific thickness is formed on a heat-resistant resin film substrate having a surface roughness of 0.2 to 2.2 μm in arithmetic average height Ra, a heat-resistant light-shading film having a low surface gloss, a low reflectance and an electroconductivity can be realized. In addition, since said metal carbide film layer is formed by sputtering method, it secures denser surface structure than a light-shading film produced by a conventional coating procedure, and has improved surface wear resistance and friction resistance. In addition, since, in the heat-resistant light-shading film of the present invention, on a resin film substrate having a heat resistance of 155° C. or higher, a crystalline metal carbide layer is formed as a light-shading layer, said metal carbide material is less susceptible to oxidation and light-shading capacity hardly varies in a high temperature environment at 155 to 300° C. or a high humidity environment, therefore, it has a more superior heat resistance compared with a heat-resistant light-shading film using a conventional oxidizable metal layer as a light-shading layer. In addition, since the heat-resistant light-shading film of the present invention has a symmetrical layer structure having the heat-resistant resin film at the center sandwiched with the metal carbide layers, deformation in the sputtering time due to film stress does not occur, providing high productivity.

In addition, optimized layer-forming conditions for the metal carbide layer of the present invention by sputtering method can make said metal carbide layer denser. Due to this dense outermost layer, said heat-resistant light-shading layer does not separate in working time of light-shading blades in which said film is used, even when said film is exposed to a high temperature environment of 155 to 300° C., and peel-off of shot material, which is adhered and remained associated with matting treatment of the substrate film, specifically, surface treatment of the film by sand blasting method, does not occur.

The light intensity adjusting device of the present invention, which uses light-shading blades produced by processing said heat-resistant light-shading film, is more reduced in weight due to the light-shading blades made of resin film substrate compared with a light intensity adjusting device using light-shading blades produced by processing a conventional heat-resistant light-shading film made of metal foil plate coated with heat-resistant coating material. Therefore, when the heat-resistant light-shading film is used for diaphragm blade and the like, it improves sliding characteristics, enables down-sizing of driving motor, and leads to cost reduction.

Accordingly, the heat-resistant light-shading film of the present invention is useful for diaphragm blade material of light intensity adjusting device for liquid-crystal projectors and fixed diaphragm material in lens unit of in-vehicle monitors in which heat resistance is particularly required. The heat-resistant light-shading film of the present invention is also useful for shutter blades and the like of digital cameras and digital video cameras, and industrially extremely valuable.

### BRIEF DESCRIPTION OF THE DRAWINGS

FIG. 1 is a cross-sectional view illustrating the heat-resistant light-shading film of the present invention with a metal carbide film formed on one side of the substrate.

FIG. 2 is a cross-sectional view illustrating the heat-resistant light-shading film of the present invention with metal carbide films formed on both sides of the substrate.

FIG. 3 is a schematic diagram illustrating an example of reel-equipped style, substrate cooling type sputtering unit used for producing the heat-resistant light-shading film of the present invention.

FIG. 4 is a schematic diagram illustrating an example of reel-equipped style sputtering unit (floating method) used for producing the heat-resistant light-shading film of the present invention.

FIG. 5 is a schematic diagram illustrating an diaphragm mechanism in which the heat-resistant light-shading film is used.

FIG. 6 illustrates an X-ray diffraction pattern for the light-shading layer (titanium carbide layer) of the heat-resistant light-shading film produced by the method of the present invention.

FIG. 7 is an X-ray diffraction pattern for the light-shading layer (tungsten carbide layer) of the heat-resistant light-shading film produced by the method of the present invention.

### NOTATION

1 Resin film substrate
2 Metal carbide layer
5 Wind-off roll
6 Vacuum pump
7 Vacuum chamber
8 Cooling can roll
9 Take-up roll
10 Magnetron cathode
11 Target
12 Barrier
13 Support roll
14 Heat-resistant light-shading blade
15 Guide hole
16 Guide pin
17 Pin
18 Substrate
19 Hole
20 Opening

### DETAILED DESCRIPTION OF THE INVENTION

Hereinafter, the heat-resistant light-shading film of the present invention, method for producing the film, applications to light intensity adjusting devices and diaphragms will be described by referring to the drawings.

### 1. Heat-Resistant Light-Shading Film

The heat-resistant light-shading film of the present invention comprises a resin film substrate (A) having a heat resistance of 155° C. or higher and a light-shading layer (B) of crystalline metal carbide layer (MeC) formed on one side or both sides of the resin film substrate (A), characterized in that the light-shading layer (B) has a thickness of 100 nm or more, a surface roughness of 0.1 to 2.1 μm (arithmetic average height Ra), and a content of carbon element (C) in the metal carbide layer (MeC) of 0.3 or more in atomic number ratio to the total metal elements (Me).

The heat-resistant light-shading film having low surface gloss and low reflectance can be realized by forming a light-shading layer having a surface roughness as described above or by covering the surface of said light-shading layer with metal carbide to provide similar surface roughness to the surface. Therefore, when the heat-resistant light-shading film is used as a fixed diaphragm of digital image-taking devices, diaphragm blades of mechanical shutter devices or blade material for light intensity adjusting device of liquid-crystal projectors, appearance of stray light generated by reflected light in optical system can be avoided.

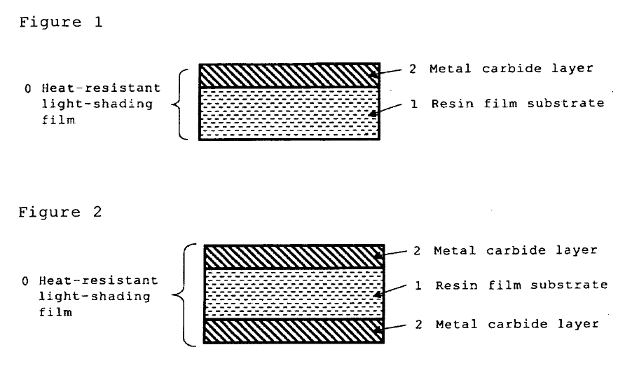

FIG. 1 and FIG. 2 are schematic diagrams showing a structure of the heat-resistant light-shading film according to the present invention. The heat-resistant light-shading film of the present invention is constructed from the resin film 1 as a substrate and the metal carbide layer 2 formed on the surface thereof. And surface roughness of the metal carbide layer 2 is 0.1 to 2.1 μm (arithmetic average height Ra), more preferably 0.2 to 2.0 μm, and most preferably 0.3 to 1.9 μm. Surface roughness less than 0.1 μm or over 2.1 μm is not desirable in terms of low surface gloss or susceptibility to surface defect.

The above metal carbide layer 2 may be formed on one side of the resin film substrate as shown in FIG. 1, but preferably formed on both sides as shown in FIG. 2. When the metal carbide layer 2 is formed on both sides, it is more preferable that the heat-resistant light-shading film has a symmetric structure having the resin film substrate in the center sandwiched with the two metal carbide layers 2 having same structure and thickness. The thin layer formed on the substrate becomes a factor to cause deformation due to a stress which is given to the substrate. The deformation due to a stress sometimes appears in the heat-resistant light-shading film just after film-forming, and tends to become greater and remarkable particularly when the film is heated to around 155 to 300° C. However, by using the metal carbide layers having the same material and thickness formed on the both sides of the substrate and employing the symmetric structure having the substrate in the center, well-balanced stress is maintained even under heated conditions and a flat heat-resistant light-shading film can be easily realized.

### (A) Resin Film Substrate

The resin film substrate (A) to be used for the heat-resistant light-shading film of the present invention is not particularly limited so long as it is a heat-resistant resin film substrate having a heat resistance of 155° C. or higher, but preferably a material composed of at least one type of material selected from polyethylene naphthalate, polyimide, aramid, polyphenylene sulfide or polyether sulfone. Among them, polyethylene naphthalate can be used in an environment of 155 to 200° C. because it has a heat resistance of around 200° C., and is useful as an industrial material due to very cheap price. In addition, polyimide film, aramid, polyphenylene sulfide or polyether sulfone has a heat resistance of 200° C. or higher and can be used in an environment of 200° C. or higher. In particular, polyimide is most preferable film because it has the highest heat-resistant temperature of 300° C. or higher.

In addition, the resin film to be used as a substrate may consist of a transparent resin or a colored resin with a pigment kneaded, but must have a heat resistance of 155° C. or higher. Here, the “film having a heat resistance of 155° C. or higher” means a film having a glass transition point of 155° C. or higher, and in the case of a material which does not have a glass transition point, a film which does not show degeneration at a temperature of 155° C. or higher. Type of the resin material is desirably a material having flexibility so that roll coating by sputtering can be employed in consideration of mass-productivity.

Thickness of the resin film substrate is preferably in a range of 5 to 200 μm, more preferably 10to 150 μm, and most preferably 20 to 125 μm. A thickness less than 5 μm makes the film susceptible to surface defect such as damages or folds, and a thickness over 200 μm makes it difficult to mount a plurality of light-shading blades to diaphragm devices or light intensity adjusting devices in which downsizing is progressing.

In addition, the resin film substrate of the heat-resistant light-shading film of the present invention preferably has a surface roughness (arithmetic average height Ra) of 0.2 to 2.2 μm, in particular has a fine irregular structure of 0.3 to 2.1 μm. Ra less than 0.2 μm makes it difficult to obtain sufficient adhesion of the metal carbide layer formed on the film surface, and also sufficient low surface gloss and low reflectance. Contrary, Ra over 2.2 μm makes it difficult to form the metal carbide layer in concave portions due to too large concavity and convexity on the film surface. In order to fully cover the film surface to obtain sufficient light-shading capacity, thickness of the metal carbide layer becomes too thick. This is not preferable because of high cost.

Arithmetic average height is also referred to as arithmetic average roughness, and is a average value obtained by taking out a roughness curve within a standard length along the direction of the average line, summing up absolute values of deviations of the measured curve from the average line within the standard length, and calculating the average value.

The concavity and convexity on the resin film surface is formed by subjecting the film surface to surface treatment. Prescribed surface concavity and convexity can be formed, for example, by nano-imprinting processing or matting treatment using a shot material. In the case of the matting treatment, although the matting treatment processing, in which sand is used for shot material, is general, the shot material is not limited thereto. The concavity and convexity of the optimum Ra value depends on the film transfer speed and type and size of the shot material. Thus, the surface treatment is carried out by optimizing these conditions so that the value of arithmetic average height Ra value becomes 0.2 to 2.2 μm. The film after matting treatment is dried after removing the shot material by washing. In the case when a metal carbide layer is formed on the both side of film, both side of film are matting treated.

### (B) Light-Shading Layer (Metal Carbide Layer)

The heat-resistant light-shading film of the present invention has a sufficient heat resistance even in such a high temperature environment as 155° C. This is because the resin film substrate has a heat resistance and also the light-shading metal carbide layer has a heat resistance.

Since metal layer generally becomes more transparent when it is oxidized, oxidation resistance must be provided when it is used as a light-shading layer. The material of the light-shading film to be used for the heat-resistant light-shading layer of the present invention employs metal carbide layer which is superior in oxidation resistance.

The metal carbide layer (MeC) of the present invention is preferably mainly composed of one or more kinds of materials selected from silicon carbide, titanium carbide, aluminum carbide, niobium carbide, tungsten carbide, molybdenum carbide, vanadium carbide, tantalum carbide, zirconium carbide or hafnium carbide. These metal carbide layers are not only more oxidation-resistant at 155 to 300° C. compared with conventional metallic layers (silicon, titanium, aluminum, niobium, tungsten, molybdenum, vanadium, tantalum, zirconium and hafnium) but also superior in abrasion resistance due to their hardness. On the contrary, when conventional metals (silicon, titanium, aluminum, niobium, tungsten, molybdenum, vanadium, tantalum, zirconium and hafnium) are utilized as a light-shading layer, their surfaces must be applied with some other material having oxidation resistance and hardness (metal oxide and DLC) as a protection layer, because they are insufficient in oxidation resistance or hardness at such high temperature as described above. As a result, this leads to a complicated structure and high cost.

In addition, as for structure of the metal carbide layer (MeC) to be used in the present invention, ratio of carbon element (C) to the total metal elements (Me) in the layer is 0.3 or more, preferably 0.5 or more, and particularly 0.7 or more in atomic number ratio C/Me. An atomic number ratio C/Me of less than 0.3 cannot provide a sufficient oxidation resistance under a high temperature heating at 155 to 300° C.

The metal carbide layer formed on the resin film as a light-shading layer must be a crystalline layer. This is because crystalline film exhibits strong adhesion to the resin film substrate. If the metal carbide layer is an amorphous layer, crystallization of the layer proceeds when it is used in a high temperature environment. If crystallization of the layer proceeds, not only discoloration occurs but also film stress is generated in the crystallized area, hence the heat-resistant light-shading film loses stress balance to become easily deformable, causing a problem.

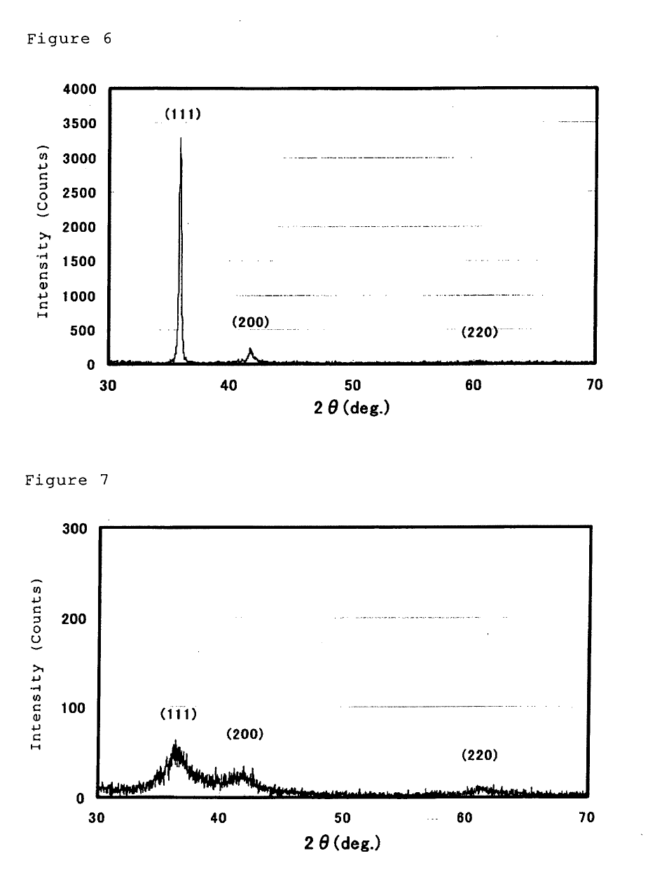

Since the metal carbide (MeC) layer is a material which is made by penetration of carbon (C) into a crystal of the metal component (Me), it is more difficult to crystallize compared with a metallic layer of the metal component (Me). In addition, penetration of carbon into a crystal of the metal component makes bonds between each element to have more ratio of covalent nature, and this makes crystallization more difficult compared with the metal material constructed by metallic bond which does not contain carbon. A layer having an atomic number ratio C/Me of 0.3 or more which exhibits good heat resistance is particularly difficult to crystallize. It can be evaluated whether a metal carbide layer is crystalline layer or not, by examining existence or nonexistence of diffraction peak(s) in X-ray diffraction measurement, or by examining existence or nonexistence of crystalline grains by cross-sectional observation of the layer using a TEM. When degree of crystallinity is high, clear diffraction peaks like those in FIG. 6 exist.

As described above, surface roughness of the metal carbide layer (MeC) of the present invention must be 0.1 to 2.1 μm (arithmetic average height Ra), more preferably 0.2 to 2.0 μm, and most preferably 0.3 to 1.9 μm. A surface roughness of less than 0.1 μm or over 2.1 μm is not preferable in terms of low surface gloss or susceptibility to surface defect, respectively.

Thickness of the metal carbide layer (MeC) of the present invention is 110 to 550nm, preferably 110 to 400 nm, and more preferably 110 to 300 nm. A thickness less than 110 nm is not preferable because the layer does not have sufficient light-shading function due to light transmission occurring through the layer. Thicker film more improves light-shading capacity. A thickness over 550 nm, however, results in increase of production cost due to increased material cost and prolonged film-forming time, as well as increase in film stress which leads to easy deformation. By setting thickness of the metal carbide layer to such level as described above, sufficient light-shading capacity, low film stress, and low production cost can be attained.

Further, a surface roughness Ra of 0.1 to 2.1 μm must be obtained by forming such metal carbide layer. Such surface roughness can reduce light reflectance in a wavelength range from 380 to 780 nm to 10% or less. As for light-shading capacity, preferably optical density is 4 or more, or transmittance is 1% or less, in particular, 0%.

It should be noted that the above metal carbide layer may contain nitrogen. Introduction of nitrogen into the metal carbide layer is possible by carrying out the sputtering by introducing a mixed gas containing nitrogen gas as a sputtering gas when the metal carbide layer is formed, alternatively such element can be also introduced by using a target containing nitrogen without using a mixed gas as described above.

In addition, the metal carbide layer of the present invention preferably is not to contain oxygen as less as possible to maintain a high adhesion with the resin film and a high light-shading capacity. However, oxygen contained in the target or oxygen remaining in the sputtering chamber may be incorporated and contained in a part or the whole of the metallic layer, so long as the oxygen is in such a level as not to impair the metallic nature, a high light-shading capacity, and a high adhesion to the resin film.

Content of such oxygen contained in the metal carbide layer (MeC) as an unavoidable component in a ratio of oxygen element contained (O) to the total metal elements (Me) is preferably 0.5 or less, and more preferably 0.1 or less in atomic number ratio O/Me. This is because a content of contained oxygen element (O) of over 0.5 in atomic number ratio O/Me increases transmittance (reduce optical density) in a wavelength range from 380 to 780 nm, and sufficient light-shading function cannot be obtained. A content of 0.5 or less in atomic number ratio O/Me can provide a sufficient light-shading capacity leading to reduction of production cost even with such a thinner film thickness as 110 to 400 nm. However, when atomic number ratio O/Me is over 0.5 but 0.8 or less, a sufficient light-shading capacity can be also obtained by using such a thicker film as 400 to 550 nm.

Atomic number ratio O/Me in the metal carbide layer can be measured, for example, by an XPS (X-ray photoelectron spectroscopy). The atomic number ratio O/Me in a layer can be quantified by measuring after removing a surface layer of 20 to 30 nm by sputtering in vacuum, because a more oxygen atoms are bound in the outermost surface of layer.

The metal carbide layer of the heat-resistant light-shading film of the present invention may be constituted by laminated layers composed of plural types of metal carbide layers having different composition (content and kind of metal element, carbon content, nitrogen content, oxygen content). Lamination of plural types of metal carbide layers having different optical constants can bring an optical interference effect and control reflection characteristics.

It should be noted that the light-shading film of the present invention may be used by coating another thin layer (e.g., fluorine-containing organic layer) having lubricating characteristics and low abrasion characteristics in a thin layer on the surface of the above metal carbide layer, so long as the features of the present invention are not impaired.

### 2. Production Method of the Heat-Resistant Light-Shading Film

The production method of the heat-resistant light-shading film of the present invention is a method for producing a heat-resistant light-shading film comprising a resin film substrate (A) having a heat resistance of 155° C. or higher and a metal carbide layer (MeC) as a light-shading layer (B) formed on one side or both sides of the resin film substrate (A), characterized by comprising steps for supplying the resin film substrate (A) having a surface roughness of 0.2 to 2.2 μm (arithmetic average height Ra) to a sputtering unit; and for forming a crystalline metal carbide layer (MeC) having a thickness of 100 nm or more, a surface roughness of 0.1 to 2.1 μm (arithmetic average height Ra), and a content of carbon element (C) in the metal carbide layer (MeC) of 0.3 or more in atomic number ratio (C/Me) to the total metal elements (Me), on said resin film substrate (A) by the sputtering method using a metal carbide target in an inert gas atmosphere.

Layer-forming method for the metal carbide layer is preferably gas phase synthesis such as CVD and PVD. Among them, sputtering method and ion plating method are industrially more preferable because a dense film having superior quality can be formed uniformly ranging a large area. A layer formed by the sputtering method or the ion plating method has features such as a denser structure compared with those formed by the ink coating method or the vacuum evaporation method, and hence a good adhesiveness to an under-layer (substrate and film layer).

These characteristics become more significant when the heat-resistant light-shading film is used in a high temperature environment of 155 to 300° C. When the film is formed by the ink coating method, peel-off of the layer and change in color due to oxidation of the layer are observed. On the contrary, the layer formed by the sputtering method as in the present invention is preferable because such problems hardly occur.

The sputtering method is a thin-layer-forming method which is effective when a layer of material having a low vapor pressure is formed on a substrate or when precision layer thickness control is required. In this method, layer is generally formed by using a substrate as an anode and a sputtering target providing a layer material as a cathode, under the argon gas atmosphere at a pressure of about 10 Pa or lower, inducing glow discharge between the electrodes to produce an argon plasma, bombarding an argon cation in the plasma against the sputtering target of the cathode to flick particles of the sputtering target component, and depositing these particles on the substrate.

The above sputtering method can be classified by how an argon gas plasma is produced, e.g., to the RF (Radio Frequency) sputtering using RF plasma, DC (Direct Current) sputtering using DC plasma, and magnetron sputtering in which layer is formed-by arranging a magnet on the backside of the sputtering target to focus an argon plasma just above the sputtering target to secure an increased bombardment efficiency of argon ions even under a low gas pressure.

As a method to obtain a metal carbide layer by the sputtering method, there are several methods. One is a method using a metal carbide target and another one is a method in which sputtering layer-forming is carried out by introducing a hydrocarbon gas etc. as a carbon source into a sputtering gas with using a metal target. Also, there is a method in which metal carbide layer is obtained by carrying out with sputtering layer-forming a metal target and a carbon target at a same time to deposit the metal component and the carbon component on a substrate. Among them, the method using a metal carbide target is simple and preferable because layer composition and layer characteristics are stable and the sputtering layer-forming can be carried out in a pure argon gas atmosphere.

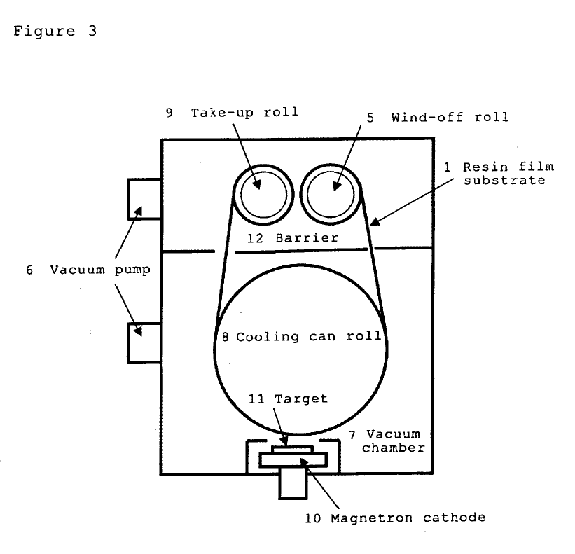

The metal carbide layer may be formed on the resin film by, for example, a reel-equipped style sputtering unit illustrated in FIG. 3. This unit has a structure in which a rolled resin film substrate 1 is set on a wind-off roll 5, contents in a vacuum chamber 7, which is a layer-forming chamber, are evacuated by a vacuum pump 6 such as turbomolecular pump, and the film 1 transferred from the roll 5 is taken up on a take-up roll 9 after passing over a surface of a cooling can roll 8. A magnetron cathode 10 is disposed to face the surface of the cooling can roll 8, and this cathode is provided with a target 11 which is a raw material for the layer. It should noted that the film transfer section, comprising the wind-off roll 5, cooling can roll 8, take-up roll 9 and the like is isolated from the magnetron cathode 10 by a barrier 12.

Firstly, the rolled resin film substrate 1 is first set on the wind-off roll 5, contents in the vacuum chamber 7 are evacuated by a vacuum pump 6 such as turbomolecular pump. Then, the resin film substrate 1 supplied from the wind-off roll 5 is taken up on the take-up roll 9 after passing over the surface of the cooling can roll 8 on the way thereto, while discharges are generated between the cooling can roll 8 and the cathode to form the layer on the resin film substrate 1 being transferred in close contact with the cooling can roll surface. It should be noted that, it is desirable that the resin film substrate is dried by heating at a temperature around the glass transition temperature before being subjected to sputtering.

In the heat-resistant light-shading layer of the present invention, the metal carbide layer is formed on the resin film substrate, for example, by DC magnetron sputtering method using a sputtering target of the metal carbide in the argon atmosphere.

It is essential that the metal carbide film as a light-shading film formed on the resin film substrate is a crystalline film as described above. Since the metal carbide (MeC) film is a material which is made by penetration of carbon (C) into a crystal of the metal component (Me), it is more difficult to crystallize compared with a metallic layer of the metal component (Me) In addition, penetration of carbon into a crystal of the metal component makes bonds between each element to have more covalent nature, and this makes crystallization more difficult compared with the metal material constructed by metallic bond which does not contain carbon. A layer having an atomic number ratio C/Me of 0.3 or more which exhibits good heat resistance is particularly difficult to crystallize.

Further, crystal growth in a thin film greatly depends on type and surface shape of the substrate. When an inorganic layer such as a metal carbide layer, is grown up, formation of a layer having a good crystallinity on an organic substrate is more difficult than on an inorganic material substrate such as a metal oxide layer. In addition, sputtered particles arrived at the substrate can align more easily in a crystal by migration, as flatness of substrate surface becomes better. However, in the case of a substrate surface having a large concavity and convexity as in the present invention, crystal alignment of incident sputtered particles by migration is difficult, and a thin film having a good crystallinity becomes difficult to obtain.

Realization of the heat-resistant light-shading film of the present invention superior in heat resistance and durability depends on how a dense metal carbide layer having a good crystallinity is formed on the surface of a heat-resistant resin film having a large concavity and convexity.

In the present invention, in order to obtain a dense metal carbide layer having a good crystallinity by the sputtering method from a metal carbide target on the surface of a heat-resistant resin film having a large concavity and convexity, controls of sputtering gas pressure and film surface temperature in the period of layer-forming are particularly important.

In the layer-forming by sputtering, a layer is generally formed by creating plasma using an inert gas under a gas pressure of 10 Pa or less, but layer-formation is preferably carried out under a specified gas pressure to obtain a metal carbide layer having a good crystallinity which is useful for a light-shading layer of the heat-resistant light-shading film. A gas pressure in layer-forming when a metal carbide layer having a good crystallinity is formed is, though not described categorically because it varies depending on type of unit, and the like, preferably 1.0 Pa or less, e.g., 0.2 to 1.0 Pa. Under this condition, since sputtered particles arriving at the substrate (resin film) have high energy, a crystalline metal carbide layer is formed on the heat-resistant resin film substrate, and a strong adhesion is exhibited between the film and resin film.

Consequently, even if a small amount of shot material using at matting treatment remains on the resin film substrate, peel-off of the layer in a high temperature environment, e.g., at 155 to 300° C., is avoided regardless of a difference in thermal expansion coefficients between the shot material and the metal carbide layer. A gas pressure in layer-forming less than 0.2 Pa makes the argon plasma in sputtering unstable due to too low gas pressure, making the resulting layer of poor quality. Also, when a gas pressure is less than 0.2 Pa, recoil argon particles sputter again the film deposited on the substrate, making it easy to inhibit formation of a dense layer. In addition, when a gas pressure in the period of film-forming is over 1.0 Pa, crystal of the layer is difficult to grow up because energy of the sputtered particles arriving at the substrate is too low, grain of the metal carbide layer becomes coarse, and layer quality becomes less dense and less crystalline. This makes adhesion to the resin film substrate weak, resulting in peel-off of the layer. Such layer cannot be used as a light-shading layer for a heat-resistance use.

Temperature of the film surface in layer-forming affects on crystallinity of the metal carbide layer. As temperature of the film surface in layer-forming becomes higher, crystal alignment of the sputtered particles becomes easier and crystallinity becomes better. However, a temperature to which the heat-resistant resin film can be heated has a limit, and even with a polyimide film which is one of the most heat-resistant films, layer-formation has to be carried out at a surface temperature of 400° C. or lower. Under such condition, a metal carbide layer having a high adhesiveness to the resin film can be obtained. Therefore, when a heat-resistant light-shading film which can be used in a high temperature environment is formed, the surface temperature is particularly important. Optimum film surface temperature in layer-forming is, though it cannot be described categorically because it varies depending on type of film substrate to be used, for example, preferably 155° C. or higher to obtain a heat-resistant light-shading film to be used in an environment of 100 to 155° C.

Thus, a heat-resistant light-shading film composed of a metal carbide layer, which is dense and superior in adhesiveness to the resin film substrate and crystallinity, can be obtained even in an environment of 100 to 155° C. In this case, a resin film having a heat resistance of 155° C. or higher is naturally used. In addition, in order to obtain a heat-resistant light-shading film to be used in an environment at a temperature over 155° C., in particular, in a high temperature environment of around 200 to 300° C., the film surface temperature in layer-forming is desirably a high temperature of 180 to 220° C., or 220° C. or higher, and a temperature to which the resin film substrate is resistant or lower. Under this condition, a heat-resistant light-shading film having a dense layer quality and superior adhesiveness to a resin film substrate having a heat resistance of 200° C. or higher can be obtained.

In this regard, however, to obtain a light-shading film to be used at a temperature of room temperature to 130° C., even the film surface temperature of 50 to 100° C. is sufficient. However, a crystalline metal carbide layer is particularly difficult at a film surface temperature of 50 to 100° C., and layer-forming under a sputtering gas pressure in a range of 0.2 to 1.0 Pa becomes absolutely essential. Under this condition, a heat-resistant light-shading film composed of a metal carbide layer having a superior adhesiveness to a resin film substrate can be obtained even in an environment of room temperature to 130° C.

The resin film substrate is naturally heated by the plasma in the period of layer-forming. The resin film substrate surface can be easily kept at 155 to 220° C. by thermoelectrons flowing from the target to the substrate and radiated heat from the plasma, and by adjusting the gas pressure, power supplied to the target and film transfer speed. The natural heating effect by the plasma increases as gas pressure decreases, power supplied to the target increases or film transfer speed decreases. The temperature of resin film surface is much hotter than the cooling can by naturally heated effect even when the film at layer-forming is in contact with the cooling can. However, in unit of FIG. 3, temperature of film surface by naturally heating greatly depends on temperature of the cooling can, because the film is transferred while being cooled by the cooling can. In order to utilize the natural heating effect as much as possible in the layer-forming, it is effective to increase cooling can temperature and decrease film transfer speed.

Thickness of the metal carbide layer is controlled by film transfer speed and power supplied to the target, and becomes thicker as film transfer speed decreases and power supplied to the target increases.

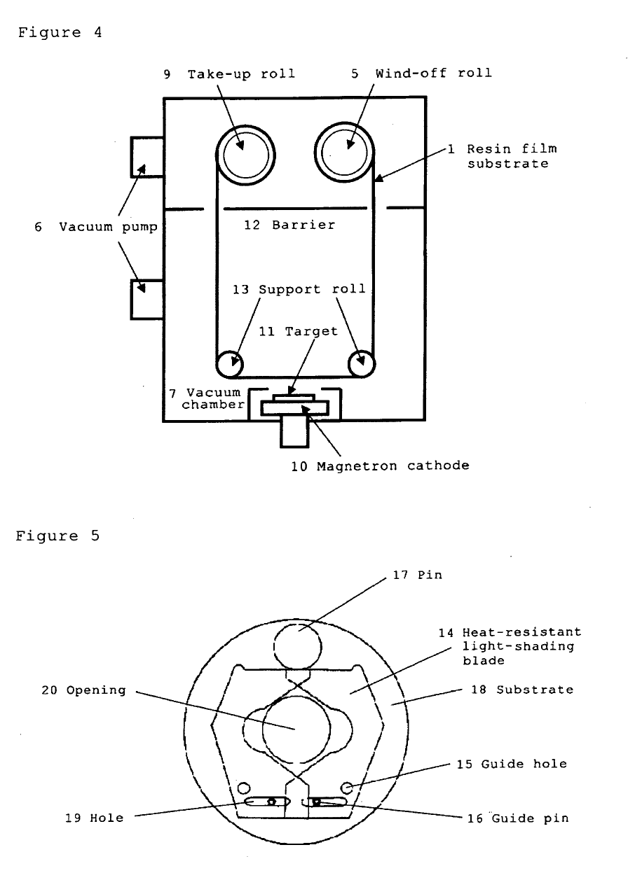

In addition, in FIG. 4, an unit which has a different film transfer system from the above unit is illustrated. Since this unit employs a layer-forming method (floating method) in which the film is subjected to the sputtering without being cooled by the cooling can, the naturally heating effect can be efficiently utilized. In this method, the film is supported by two support rolls 13 locating apart from the target, and the film facing the target 11 is subjected to the sputtering while it is floating in the layer-forming chamber (vacuum chamber 7) without being cooled on the back side. Since the layer-forming chamber is kept under a vacuum and the heat irradiated from the target and plasma and accumulated on the film is hardly released, the film can be efficiently heated, and the naturally heating effect to practically 270° C. or higher can be easily realized.

Temperature of the substrate surface in the period of layer-forming can be determined by a radiation thermometer. Temperature attained on the film can be also determined by a thermolabel attached to the surface by observing change of label color after the layer-forming.

As described above, a heat-resistant light-shading film in which a metal carbide layer is formed with high adhesiveness on one side of the resin film substrate can be obtained. A heat-resistant light-shading film in which a metal carbide layers are formed on both sides can be obtained by further supplying the resultant heat-resistant light-shading film to the above sputtering unit and forming the metal carbide layer by the sputtering on the back side of the resin film substrate in the same manner in sequence.

In addition, formation of a metal carbide layer was described in detail taking a continuous process by a film reel-equipped style sputtering unit as an example. However, the present invention is not limited to this method. For example, a batch style layer-forming method in which the film is formed without transferring the film substrate can be employed. In this case, however, additional operations for changing atmosphere gas, transfer/stopping of the film make the layer-forming process cumbersome. Further, the substrate film is not necessarily be rolled, and it may be fixed in the sputtering unit after being cut into a given size.

### 3. Use of Heat-Resistant Light-Shading Film

The heat-resistant light-shading film of the present invention obtained by the above production method may be punched in a specified shape in such a manner that cracking in the end face does not occur, and used for fixed diaphragms or mechanical shutter blades for digital cameras or digital video cameras, diaphragm (iris) allowing passage of only a certain quantity of light, or for diaphragm blades for light intensity adjusting device (auto-iris) of liquid crystal projectors.

In particular, fixed diaphragms in lens unit for in-vehicle digital video cameras are extremely heated by sunlight in summer season and also light intensity adjusting device of liquid crystal projectors are extremely heated by irradiated light from lamp. Therefore, the diaphragm blades having a high heat-resistant light-shading capacity obtained by processing the heat-resistant light-shading film of the present invention are useful. In addition, when a production process where optical members are assembled by reflow process is employed, fixed diaphragms and mechanical shutter blades obtained by processing the heat-resistant light-shading film of the present invention are useful because their characteristics do not change even under a heated environment.

FIG. 5 is a schematic diagram illustrating an diaphragm mechanism of a light intensity adjusting device mounted the heat-resistant light-shading blades 14 produced by punching. The heat-resistant light-shading film blades 14 are provided with guide holes 15, a guide pin 16 connected to a driving motor and hole 19 by which the blades are set on a substrate board 18 provided with a pin 17 for controlling a position at which the blades work. The substrate board 18 is provided with an opening 20 at the center, through which light from a lamp is passed. The light-shading blade can take various shapes depending on the diaphragm device structure. Moreover, the blade of the heat-resistant light-shading film of the present invention with a resin film as the substrate can have a reduced weight, and hence size of driving members for driving the shading blade and also power consumption can be reduced.

### EXAMPLES

Next, the present invention will be described more specifically by Examples and Comparative Examples. It should be noted that, the resultant heat-resistant light-shading films were evaluated by the following procedures.

### (Optical Density and Reflectance)

Optical density and reflectance of the obtained heat-resistant light-shading films were determined by measuring light-shading capacity and reflectance (regular reflectance) for the visible light in a wavelength range from 380 nm to 780 nm using spectrophotometer. Optical density as an index of light-shading capacity was converted from transmittance (T) measured by spectrophotometer by the following equation:

Optical density=Log (1/T).

Optical density should be 4 or more and maximum reflectance should be less than 10%.

### (Surface Gloss)

Surface gloss of the obtained heat-resistant light-shading films was determined by a gloss meter in accordance with JIS Z8741. The film is considered to have a good surface gloss when it is below 3%.

### (Friction Coefficient)

Static and dynamic friction coefficients of the obtained heat-resistant light-shading films were determined in accordance with JIS D1894. The film was judged as good when its static and dynamic friction coefficients were 0.3 or less

### (Surface Roughness)

Arithmetic average height Ra of the obtained heat-resistant light-shading films was determined by a surface roughness meter (Surfcom 570A, manufactured by Tokyo Seimitsu Co., Ltd.). The film should have a surface roughness of 0.1 to 2.1 μm (arithmetic average height Ra)

### (Crystallinity of Light-Shading Layer)

Crystallinity of the light-shading layer was determined by X-ray diffraction measurement. The measurement was carried out using X'PertPROMPD (manufactured by PANalytical Co., Ltd.) under the broad-spectrum measurement conditions using Cu Ka-ray at a voltage of 45 kV and electric current of 40 mA. Crystallinity of a film was evaluated by existence or nonexistence of an X-ray diffraction peak. Crystallinity was also evaluated from existence or nonexistence of crystal grains in a cross-sectional observation of layer by a TEM.

### (Composition of Light-Shading Layer)

Composition (atomic number ratio C/Me) of the light-shading layer was determined by quantitative analysis using an XPS and an EPMA (electron probe micro analyzer). In addition, content of oxygen (atomic number ratio O/Me) in the light-shading layer was quantitatively analyzed by an XPS. Composition analysis by XPS was carried out after removing the surface layer of 20 to 30 nm by sputtering in vacuum. The film should have C/Me of 0.3 or more and O/Me of 0.5 or less.

### (Heat Resistance)

Heat resistance characteristic of the obtained heat-resistant light-shading films was evaluated by the following procedures. The resultant heat-resistant light-shading film was left in an oven (manufactured by Advantech) set and heated at the prescribed heating temperatures (130, 155 and 250° C.) for 24 hours, then taken out. The film was rated as “good (o)” when no warpage or no discoloration of film was found, and “insufficient (x) when warpage or discoloration of film was found.

### (Adhesiveness)

Adhesiveness of the obtained heat-resistant light-shading films was evaluated in accordance with JIS C0021. The film was judged as “good (o)” when no peel-off of layer was observed, and “insufficient (x) when peel-off of layer was observed.

### (Electroconductivity)

Electroconductivity of the obtained heat-resistant light-shading films was evaluated in accordance with JIS K6911.

### Example 1

Using a reel-equipped sputtering unit illustrated in FIG. 3, a metal carbide layer was formed on a resin film substrate having a heat resistance of 200° C. or higher. First, a target 11 providing a layer material was set on a magnetron cathode 10 which was set in such a manner to face to the surface of a cooling can roll 8. A film transfer section comprising a wind-off roll 5, a cooling can roll 8, a take-up roll 9, and the like, was isolated from the magnetron cathode 10 with a diaphragm 12. Next, a rolled resin film substrate 1 was set on the wind-off roll 5.

As the resin film substrate, a polyimide (PI) film, having a thickness of 75 μm and a surface with a fine concavity and convexity structure with an arithmetic average height Ra of 0.5 μm obtained by applying a surface treatment by sand blasting, was used. This polyimide (PI) film was sufficiently dried by heating at a temperature of 200° C. or higher before sputtering.

Next, contents in a vacuum chamber 7 were evacuated by a vacuum pump 6 such as turbomolecular pump, and discharges were generated between the cooling can roll 8 and cathode, and the layer was formed while the resin film substrate 1 running in close contact with the cooling can roll surface. A degree of vacuum attained in the vacuum chamber before starting the layer-forming was 2×10⁻⁴ Pa or less.

First, a sintered titanium carbide target (C/Ti atomic number ratio: 0.8) was set on the cathode, with which a titanium carbide layer was formed by DC sputtering method. The titanium carbide layer was formed using a high-purity (99.999%) argon gas as a sputtering gas under a sputtering gas pressure of 0.6 Pa. Thickness of the titanium carbide layer was controlled by film transfer speed and power supplied to the target in the layer-forming period. The resin film substrate 1 transferred from the wind-off roll 5 was taken up by a take-up roll 9 after passing over the surface of the cooling can roll 8.

Film surface temperature in the sputtering time of the titanium carbide layer was measured through an inspection window of quartz glass in the reel-equipped sputtering unit by an infrared radiation thermometer, and found to be 200 to 210° C.

A titanium carbide layer having a thickness of 200 nm was formed on the both sides of a polyimide (PI) film having a thickness of 75 μm to prepare a heat-resistant light-shading film. Surface of the polyimide (PI) film had been treated by sand blasting under the prescribed conditions of discharge time, discharge pressure and transfer speed, to have a fine concavity and convexity structure with an arithmetic average height Ra of 0.5 μm on the both sides. Such layer-formation was repeated for each side to produce a light-shading film having a center-symmetric structure with the polyimide (PI) film substrate.

Next, the heat-resistant light-shading film thus produced was evaluated by the procedures described above. It was confirmed from the results of the quantitative analyses by an XPS and an EPMA that structure of the obtained titanium carbide layer was the same to a target composition (atomic number ratio C/Ti was 0.8). Further, content of oxygen in the layer was found to be 0.3 in atomic number ratio O/Me from the quantitative analysis by an XPS.

Crystallinity of the film was measured by the X-ray diffraction, and a pattern as illustrated in FIG. 6 was obtained. The pattern showed peaks attributable to a TiC crystal structure, demonstrating the layer being superior in crystallinity. In addition, from an observation of a cross-section of the layer by a TEM, it was found that the layer was composed of crystal grains.

In addition, optical density in the visible region (a wavelength range from 380 to 780 nm) was 4 or more, and maximum reflectance was 7%. In addition, surface gloss was less than 3%. Static and dynamic friction coefficients were as good as 0.3 or less. In addition, surface resistance was 98 Ω/□ (read as “ohm per square”), and arithmetic average height Ra of the surface was 0.4 μm.

The heat-resistant light-shading film after heating exhibited no warpage or discoloration. Peel-off of layer was not found and adhesiveness was good. No change after heating was found also in light-shading capacity, reflection characteristics, surface gloss and friction coefficient. These evaluation results are shown in Table 1.

The resultant heat-resistant light-shading film was good in all of optical density, reflectance, surface gloss, heat resistance, friction coefficient and electroconductivity. Thus, it can be understood that such heat-resistant light-shading film can be used as a member for liquid crystal projectors such as diaphragm, to be used in a high temperature environment.

### Example 2

A heat-resistant light-shading film was prepared under the same conditions as in Example 1 except that only thickness of the titanium carbide layer was changed to 110 nm by varying film transfer speed in sputtering. Kind of the target material, type, thickness and surface roughness of the polyimide were same to those in Example 1. Degree of vacuum in the vacuum chamber attained before starting the sputtering was 6×10⁻⁵ Pa or less. Content of carbon in the light-shading layer was same to that in Example 1. Content of oxygen in the layer quantitatively analyzed by an XPS was 0.4 in atomic number ratio O/Me. From the X-ray diffraction measurement, it was found that the layer was a TiC layer having a superior crystallinity. Cross-sectional observation by a TEM also revealed that it was a dense layer composed of crystal grains.

Evaluations (optical characteristics and heat resistance) of the resultant heat-resistant light-shading film were carried out by the same procedures and under the same conditions to those in Example 1. Film surface temperature in the sputtering time of the titanium carbide layer was measured through the inspection window of quartz glass in the reel-equipped sputtering unit by the infrared radiation thermometer in the same manner as in Example 1. The temperature was 180 to 200° C.

Characteristics in the visible region, e.g., optical density, reflectance, surface gloss, and the like, were equivalent to those in Example 1. In addition, it was confirmed that surface resistance and arithmetic average height Ra of the surface were 190 Ω/□ and 0.4 μm, respectively. In addition, evaluation of adhesiveness of the layer after a heating test at 250° C. for 24 hours exhibited no warpage or peel-off of layer, demonstrating that the film had an equivalent heat resistance characteristics to those in Example 1. Structure and characteristics of the heat-resistant light-shading film prepared are summarized in Table 1.

Thus, such heat-resistant light-shading film can be used as a member for liquid crystal projectors such as diaphragm, which is used in a high temperature environment.

### Example 3

A heat-resistant light-shading film was prepared under the same conditions as in Example 2 except that the degree of vacuum in the vacuum chamber attained before starting the sputtering was 8×10⁻⁴ Pa and that a titanium carbide layers having a thickness of 550 nm was formed on the both sides of the film substrate by repeating the sputtering 5 times on the film substrate, among the sputtering conditions in Example 2. Kind of the target material, type, thickness and surface roughness of the polyimide were same to those in Example 1.

Evaluations (optical characteristics and heat resistance) of the resultant heat-resistant light-shading film were carried out by the same procedures and under the same conditions to those in Example 1. Film surface temperature in the sputtering time of the titanium carbide layer was measured through the inspection window of quartz glass in the reel-equipped sputtering unit by the infrared radiation thermometer in the same manner as in Example 1. The temperature was 180 to 200° C.

Content of carbon in the light-shading layer was same to that in Example 1. Content of oxygen (atomic number ratio O/Ti) in the layer analyzed by an XPS was 0.8, and a little higher compared with the layers obtained in Examples 1 and 2. From an X-ray diffraction measurement of the layer, it was found that the layer was a TiC layer having a superior crystallinity. Also, from a cross-sectional observation by a TEM, it was found that it was a dense layer composed of crystal grains.

Characteristics in the visible region, e.g., optical density, reflectance, surface gloss, and the like, were equivalent to those in Example 1. Further, it was confirmed that surface resistance and arithmetic average height Ra of the surface were 80 Ω/□ and 0.3 μm, respectively. Furthermore, evaluation of adhesiveness of the layer after a heating test at 250° C. for 24 hours exhibited no warpage or peel-off, demonstrating that the film had an equivalent heat resistance characteristics to those in Example 1. Structure and characteristics of the heat-resistant light-shading film prepared are summarized in Table 1.

The content of oxygen of the layer in Example 3 is higher compared with those of the layers in Examples 1 and 2 because a degree of vacuum in the vacuum chamber during the sputtering was poor. Namely, it is considered that oxygen gas remaining in the vacuum chamber was incorporated in the layer by sputtering. Such layer having a high oxygen content cannot provide a sufficient light-shading capacity when layer thickness is less than 400 nm, due to a little higher transmittance. However, a sufficient light-shading capacity, e.g., an optical density of 4 or more, can be secured by increasing a layer thickness to such a level as 550 nm as in Example 3.

In addition, in the similar experiment, it was confirmed that a layer having an atomic number ratio O/Ti of 0.9 could attain the light-shading capacity of optical density 4 or more even with a film thickness of 450 nm or 500 nm.

Such heat-resistant light-shading film can be used as a member for liquid crystal projectors such as diaphragm, to be used in a high temperature environment.

### Comparative Example 1

A heat-resistant light-shading film was prepared under the same conditions as in Example 1 except that thickness of the titanium carbide layer was changed to 90 nm by varying film transfer speed. Kind of the target material, type, thickness and surface roughness of the polyimide were same to those in Example 1. Compositions (carbon content and oxygen content) and crystallinity of the light-shading layer were also same to the layer in Example 1. The evaluation results are shown in Table 2.

The heat-resistant light-shading film sputtered with the titanium carbide having a thickness of 90 nm on the both sides was evaluated (optical characteristics and heat resistance) by the same procedures and under the same conditions to those in Example 1. As a result, it was found that optical density was 3 and the film did not have a sufficient light-shading capacity. Thus, such film does not sufficiently work due to leak of light when the film is used for diaphragm member of liquid crystal projectors.

### Example 4

A heat-resistant light-shading film was prepared under the same conditions as in Example 1 except that a polyimide film with an arithmetic average height Ra of 0.2 μm prepared by sand blasting under the surface treatment conditions being varied. Kind of the target material, type, thickness and surface roughness of the polyimide were same to those in Example 1.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C., which was equivalent to the film temperature in Example 1. Evaluations (optical characteristics and heat resistance) of the resultant heat-resistant light-shading film were carried out by the same procedures and under the same conditions to those in Example 1. Compositions (carbon content and oxygen content) and crystallinity of the light-shading layer were same to those of the layer in Example 1. The characteristics are summarized in Table 1.

As a result, as for the characteristics such as optical density, surface gloss, and the like, equivalent levels of values to those in Example 1 had been obtained. In addition, it was confirmed that surface resistance and arithmetic average height Ra of the surface were 105 Ω/□ and 0.1 μm, respectively. Maximum reflectance in the visible region was 10%. Evaluation of adhesiveness of the layer after a heating test at 250° C. for 24 hours exhibited no warpage or peel-off of layer, showing that the layer had an equivalent heat resistance characteristics to those in Example 1. Structure and characteristics of the heat-resistant light-shading film prepared are summarized in Table 1.

Thus, such heat-resistant light-shading film can be used as a member for liquid crystal projectors such as diaphragm, which is used in a high temperature environment.

### Example 5

A heat-resistant light-shading film was prepared under the same conditions as in Example 1 except that a polyimide film with an arithmetic average height Ra of 0.8 μm prepared by sand blasting under the surface treatment conditions being varied. Kind of the target material, type and thickness of the polyimide were same to those in Example 1.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C., which was equivalent to the film temperature in Example 1.

Evaluations (optical characteristics and heat resistance) of the resultant heat-resistant light-shading film were carried out by the same procedures and under the same conditions to those in Example 1. It was confirmed that the light-shading layer was superior in crystallinity as in Example 1 and carbon content and oxygen content in the layer were about the same to those in Example 1. The characteristics are summarized in Table 1.

As a result, as for the characteristics, e.g., optical density, reflectance, surface gloss, and the like, equivalent levels of values to those in Example 1 had been obtained. Further, it was confirmed that surface resistance and arithmetic average height Ra of the surface were 90 Ω/□ and 0.7 μm, respectively. Evaluation of adhesiveness of the layer after a heating test at 250° C. for 24 hours exhibited no warpage or peel-off of layer, demonstrating that the layer had an equivalent heat resistance characteristics to those in Example 1. Thus, such heat-resistant light-shading film can be used as a member for liquid crystal projectors such as diaphragm, which is used in a high temperature environment.

### Comparative Example 2

A heat-resistant light-shading film was prepared under the same conditions as in Example 1 except that a polyimide film with an arithmetic average height Ra of 0.1 μm prepared by sand blasting under the surface treatment conditions being varied. Kind of the target material, type and thickness of the polyimide were same to those in Example 1.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C.

Evaluations (optical characteristics and heat resistance) of the heat-resistant light-shading film having the titanium carbide layers formed on the both sides of the film substrate were carried out by the same procedures and under the same conditions to those in Example 1. It was confirmed that the light-shading layer was superior in crystallinity as in Example 1 and carbon content and oxygen content in the layer were same to those in Example 1. The characteristics are summarized in Table 1. As a result, the film had an optical density of 4 or more, same to that in Example 1, but exhibited a maximum reflectance of 33% and a surface gloss of 70%, demonstrating that it was a heat-resistant light-shading film having a higher reflectance and surface gloss compared with the film in Example 2. In addition, it was confirmed that surface resistance and arithmetic average height Ra of the surface were 110 Ω/□ and 0.05 μm, respectively. Evaluation of adhesiveness of the layer after a heating test at 250° C. for 24 hours exhibited no warpage or peel-off of layer.

Such heat-resistant light-shading film having higher levels of reflectance and surface gloss cannot be used as shutter blades, and the like, because it is influenced by surface reflection.

### Comparative Example 3

A heat-resistant light-shading film was prepared under the same conditions as in Example 2 except that a polyimide film with an arithmetic average height Ra of 2.3 μm prepared by sand blasting under the surface treatment conditions being varied. Kind of the target material, type and thickness of the polyimide were same to those in Example 2.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C., which was equivalent to the film temperature in Example 1.

Evaluations (optical characteristics and heat resistance) of the heat-resistant light-shading film having the titanium carbide films having a thickness of 110 nm formed on the both sides of the film substrate were carried out by the same procedures and under the same conditions to those in Example 1. It was confirmed that the light-shading layer was superior in crystallinity as in Example 2 and carbon content and oxygen content in the layer were same to those in Example 2. The characteristics are summarized in Table 2. As a result, the film had a maximum reflectance of 4% and a surface gloss of 3% or less, same to those in Example 2, but optical density was as low as 2.0, demonstrating that it was a heat-resistant light-shading film having an insufficient light-shading capacity. Further, it was confirmed that surface resistance and arithmetic average height Ra of the surface were 86 Ω/□ and 2.2 μm, respectively. Evaluation of adhesiveness of the layer after a heating test at 250° C. for 24 hours exhibited no warpage or peel-off of layer. Structure and characteristics of the heat-resistant light-shading film prepared are summarized in Table 2.

Thus, such heat-resistant light-shading film having a low optical density allows passage of considerable quantity of light compared with the films in the above Examples, and cannot be used not only as diaphragm member for liquid crystal projectors but also for various applications in the optical field.

### Examples 6 to 8

Heat-resistant light-shading films were prepared under the same conditions as in Example 1 except that atomic number ratios C/Ti of the titanium carbide layer were varied as 0.3 (Example 6), 0.5 (Example 7) and 1.1 (Example 8) using targets having different carbon contents.

Kind, thickness and surface roughness of the polyimide, and thickness of the titanium carbide layer were same to those in Example 1. Structure and characteristics of the heat-resistant light-shading film prepared are described in Table 1.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C., which was equivalent to the film temperature in Example 1.

Evaluations (optical characteristics and heat resistance) of the resultant heat-resistant light-shading films were carried out by the same procedures and under the same conditions to those in Example 1. As a result, characteristics, e.g., optical density, reflectance, surface gloss, and the like, equivalent to those in Example 1 had been obtained. Further, it was confirmed that surface resistance and arithmetic average height Ra of the surface were 90 to 115 Ω/□ and 0.4 μm, respectively. X-ray diffractions of the light-shading layers showed a tendency that diffraction peaks becomes weaker as atomic number ratio C/Ti increases, but every layer showed a good crystallinity. Further, it was confirmed from the similar observation by a TEM that every layer was a crystalline layer. Quantitative analysis of oxygen content in the layer by an XPS resulted in atomic number ratios O/Ti of 0.2 to 0.4.

In addition, evaluation of adhesiveness of the layers after a heating test at 250° C. for 24 hours exhibited no warpage or peel-off of layer, demonstrating that the layers had equivalent heat resistance characteristics to those in Example 1.

Thus, such heat-resistant light-shading films can be used as a member for liquid crystal projectors such as diaphragm, which is used in a high temperature environment.

### Comparative Example 4

A heat-resistant light-shading film was prepared under the same conditions as in Example 1 except that atomic number ratio C/Ti of the titanium carbide layer was varied to 0.15 using a target having different carbon content. Kind, thickness and surface roughness of the polyimide, and thickness of the titanium carbide layer were same to those in Example 1. Structure and characteristics of the heat-resistant light-shading film prepared are described in Table 2.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C., which was equivalent to the film temperature in Example 1.

Evaluations (optical characteristics and heat resistance) of the resultant heat-resistant light-shading film were carried out by the same procedures and under the same conditions to those in Example 1. As a result, characteristics such as optical density, reflectance, surface gloss, and the like, equivalent to those in Example 1 had been obtained. In addition, it was confirmed that surface resistance and arithmetic average height Ra of the surface were 86 Ω/□ and 0.4 μm, respectively. Crystallinity of the layer was good and oxygen content in the layer was 0.4 in atomic number ratio O/Ti.

In addition, evaluation of the layer after a heating test at 250° C. for 24 hours showed no warpage but did occurrence of peel-off of layer and also significant color change due to a change in reflectance. Cross-sectional observation of the layer by a TEM showed that the surface and the interface facing the polyimide side of the light-shading layer had been oxidized. This oxidation is thought to be a cause of decrease in adhesiveness and color change of the layer.

Thus, such heat-resistant light-shading film cannot be used as a member for liquid crystal projectors such as diaphragm, which is used in a high temperature environment.

### Comparative Example 5

A heat-resistant light-shading film was prepared under the same conditions as in Example 1 except that a titanium layer not containing carbon, which was prepared by using a Ti target, was used as a light-shading layer. Kind, thickness and surface roughness of the polyimide, and thickness of the light-shading layer were same to those in Example 1.

Structure and characteristics of the heat-resistant light-shading film prepared are described in Table 2.

Film surface temperature in the sputtering time of the titanium layer was measured through the inspection window of quartz glass in the reel-equipped sputtering unit by the infrared radiation thermometer in the same manner as in Example 1. The temperature was 200 to 210° C., which was equivalent to the film temperature in Example 1.

Evaluations (optical characteristics and heat resistance) of the resultant heat-resistant light-shading film were carried out by the same procedures and under the same conditions to those in Example 1. As a result, characteristics such as optical density, reflectance, surface gloss, and the like, equivalent to those in Example 1 had been obtained. Further, it was confirmed that surface resistance and arithmetic average height Ra of the surface were 86 Ω/□ and 0.4 μm, respectively.

However, evaluation of the film after a heating test at 250° C. for 24 hours showed no warpage but did occurrence of peel-off of layer and also significant color change due to a change in reflectance. Cross-sectional observation of the layer by a TEM showed that the surface and the interface facing the polyimide of the light-shading layer had been oxidized. This oxidation is thought to be a cause of decrease in adhesiveness and color change of the layer.

Thus, such heat-resistant light-shading film cannot be used as a member for liquid crystal projectors such as diaphragm, which is used in a high temperature environment.

### Example 9

A titanium carbide layer same to that in Example 1 was formed on one side of a resin film substrate in a floating state using a sputtering unit illustrated in FIG. 4. As the resin film substrate, a polyimide film having a thickness of 200 μm was used. The surface of the film substrate to be sputtered had been treated by sand blasting in advance, and had a surface roughness equivalent to that in Example 1.

Evaluations (optical characteristics and heat resistance) of the resultant heat-resistant light-shading film were carried out by the same procedures and under the same conditions to those in Example 1. Film surface temperature in the sputtering time of the titanium carbide layer was measured through the inspection window of quartz glass in the reel-equipped sputtering unit by the infrared radiation thermometer in the same manner as in Example 1. The temperature was 270 to 310° C., demonstrating that natural heating effect on the film surface received from plasma was more remarkable compared with that in Example 1.

Characteristics, e.g., optical density, reflectance, surface gloss, and the like in the visible region on the sputtered side, which were equivalent to those in Example 1, had been obtained. Further, it was confirmed that surface resistance and arithmetic average height Ra of the surface were 95 Ω/□ and 0.4 μm, respectively. The layer was good in crystallinity, and carbon content and oxygen content in the layer were same to those in Example 1.

In addition, evaluation of adhesiveness of the layers after a heating test at 250° C. for 24 hours exhibited no warpage or peel-off of layer, demonstrating that the layer had equivalent heat resistance characteristics to those in Example 1. Structure and characteristics of the resultant heat-resistant light-shading film are summarized in Table 1.

Thus, such heat-resistant light-shading film can be used as a member for liquid crystal projectors such as diaphragm, which is used in a high temperature environment.

### Examples 10 to 12

### Comparative Examples 6 to 7

Heat-resistant light-shading films were experimentally produced using tungsten carbide layers having various carbon contents as a light-shading layer in the same manner as in Examples 6 to 8 and Comparative Examples 4 to 5. Resin film substrate was a polyimide film having a thickness of 50 μm. On the both sides of the film substrate, a fine concavity and convexity structure having an arithmetic average height Ra of 0.5 μm had been formed. Tungsten carbide layers or tungsten layers having a thickness of around 150 nm and different carbon contents were formed on the film substrate surface under the similar conditions to those in Examples 6 to 8 and Comparative Examples 4 to 5 and using tungsten carbide targets having different carbon contents or a tungsten target. Film surface temperature in the sputtering time of the tungsten carbide layers or tungsten layers was measured through the inspection window of quartz glass in the reel-equipped sputtering unit by the infrared radiation thermometer in the same manner as in Example 1. The temperature was 190 to 203° C.

Structures and characteristics of the resultant heat-resistant light-shading films are summarized in Table 1 and Table 2. Analyses of oxygen contents in the layers by an XPS resulted in 0.05 to 0.1 in atomic number ratios O/Me. X-ray diffractions of the light-shading layers showed a tendency that diffraction peaks becomes weaker as atomic number ratio C/W increases, but every layer showed a good crystallinity. Further, it was confirmed from the similar observation by a TEM that every layer was a crystalline layer.

Characteristics, e.g., optical density, reflectance, surface gloss, and the like in the visible region, which were equivalent to those in Example 1, had been obtained. Further, surface resistances were 83 to 123 Ω/□ demonstrating that they had an electroconductivity, and arithmetic average heights Ra of their surfaces were 0.4 μm.

In the evaluations of the layers after a heating test at 250° C. for 24 hours, the layers having an atomic number ratio C/W of 0.3 (Example 10), 0.6 (Example 11) and 0.9 (Example 12) exhibited no color change or no warpage in the adhesion test, but the layers having an atomic number ratio C/W of 0.1 (Comparative Example 6) and 0 (Comparative Example 7) exhibited occurrence of peel-off of layer and also significant color change due to a change in reflectance.

In cross-sectional observation of the layers of Comparative Examples 6 and 7 by a TEM, the layer surfaces and a part of the layer interfaces in contact with the polyimide film were oxidized, but oxidation was not observed in the layers of Examples 10 to 12. Therefore, the oxidation of the layers is thought to be a cause of decrease in adhesiveness and color change in Comparative Examples 6 and 7.

Thus, the heat-resistant light-shading films such as those in Examples 10 to 12 can be used as a member for liquid crystal projectors such as diaphragm, which is used in a high temperature environment, but the films such as those in Comparative Examples 6 and 7 cannot be used in a high temperature environment.

### Examples 13 to 15

### Comparative Examples 8 to 9

Heat-resistant light-shading films were experimentally produced using silicon carbide layers having various carbon contents as a light-shading layer in the same manner as in Examples 6 to 8 and Comparative Examples 4 to 5. Resin film substrate was a polyimide film having a thickness of 125 μm. On the both sides of the film substrate, a fine concavity and convexity structure having an arithmetic average height Ra of 0.4 μm had been formed. Silicon carbide layers having different carbon contents and silicon layers both having a thickness of around 270 nm were formed on the film substrate surface under the similar conditions to those in Examples 6 to 8 and Comparative Examples 4 to 5 and using silicon carbide targets having different carbon contents or a silicon target. Film surface temperature in the sputtering time of the silicon carbide layers or silicon layers was measured through the inspection window of quartz glass in the reel-equipped sputtering unit by the infrared radiation thermometer in the same manner as in Example 1. The temperature was 205 to 213° C.

Structures and characteristics of the resultant films are summarized in Table 1 and Table 2. Analyses of oxygen contents in the layers by an XPS resulted in 0.1 to 0.2 in atomic number ratios O/Si. X-ray diffractions of the light-shading layers showed a tendency that diffraction peaks becomes weaker as atomic number ratio C/Si increases, but every layer showed a good crystallinity. In addition, it was confirmed from the similar observation by a TEM that every layer was a crystalline film.

Characteristics such as optical density, reflectance, surface gloss, and the like in the visible region, which were equivalent to those in Example 1, had been obtained. Further, surface resistances were 105 to 156 Ω/□ showing that they had an electroconductivity, and an arithmetic average heights Ra of their surfaces were 0.3 μm.

In the evaluations of the layers after a heating test at 250° C. for 24 hours, the layers having an atomic number ratio C/Si of 0.35 (Example 13), 0.5 (Example 14) and 0.95 (Example 15) exhibited no color change or no warpage in the adhesion test, but the layers having an atomic number ratio C/Si of 0.2 (Comparative Example 8) and 0 (Comparative Example 9) exhibited occurrence of peel-off of layer in the adhesion test and also significant color change due to a change in reflectance. In cross-sectional observation of the layers of Comparative Examples 8 and 9 by a TEM, the layer surfaces and the interfaces in contact with the polyimide film were oxidized, but oxidation was not observed in the layers of Examples 13 to 15. Therefore, the oxidation of the layers is thought to be a cause of decrease in adhesiveness and color change in Comparative Examples 8 and 9.

Thus, the heat-resistant light-shading films such as those in Examples 13 to 15 can be used as a member for liquid crystal projectors such as diaphragm, which is used in a high temperature environment, but the films such as those in Comparative Examples 8 and 9 cannot be used in a high temperature environment.

### Examples 16 to 18

### Comparative Examples 10 to 11

Heat-resistant light-shading films were experimentally produced using aluminum carbide layers having various carbon contents as a light-shading layer in the same manner as in Examples 6 to 8 and Comparative Examples 4 to 5. Resin film substrate was a polyimide film having a thickness of 20 μm. On the both sides of the film substrate, a fine concavity and convexity structure having an arithmetic average height Ra of 0.6 μm had been formed. Aluminum carbide layers having different carbon contents and aluminum layers both having a thickness of around 230 nm were formed on the both sides of the film substrate under the similar conditions to those in Examples 6 to 8 and Comparative Examples 4 to 5 and using aluminum carbide targets having different carbon contents or an aluminum target. Film surface temperature in the sputtering time of the aluminum carbide layers or aluminum layers was measured through the inspection window of quartz glass in the reel-equipped sputtering unit by the infrared radiation thermometer in the same manner as in Example 1. The temperature was 200 to 210° C.

Structures and characteristics of the resultant films are summarized in Table 1 and Table 2. Analyses of oxygen contents in the layers by an XPS resulted in 0.1 to 0.2 in atomic number ratio O/Al. X-ray diffractions of the light-shading layers showed a tendency that diffraction peaks becomes weaker as atomic number ratio C/Al increases, but every layer showed a good crystallinity. In addition, it was confirmed from the similar observation by a TEM that every layer was a crystalline layer.

Characteristics, e.g., optical density, reflectance, surface gloss, and the like in the visible region, which were equivalent to those in Example 1, had been obtained. In addition, surface resistances were 82 to 125 Ω/□ showing that they had an electroconductivity, and arithmetic average heights Ra of their surfaces were 0.5 μm.

In the evaluations of the layers after a heating test at 250° C. for 24 hours, the layers having an atomic number ratio C/Al of 0.3 (Example 16), 0.7 (Example 17) and 1.0 (Example 18) exhibited no color change or no warpage in the adhesion test, but the layers having an atomic number ratio C/Al of 0.1 (Comparative Example 10) and 0 (Comparative Example 11) exhibited occurrence of peel-off of layer in the adhesion test and also significant color change due to a change in reflectance. In cross-sectional observation of the layers of Comparative Examples 10 and 11 by a TEM, the layer surfaces and the interfaces in contact with the polyimide film were oxidized, but oxidation was not observed in the layers of Examples 16 to 18. Therefore, the oxidation of the layers is thought to be a cause of decrease in adhesiveness and color change in Comparative Examples 10 and 11.

Thus, the heat-resistant light-shading films such as those in Examples 16 to 18 can be used as a member for liquid crystal projectors such as diaphragm, which is used in a high temperature environment, but the films such as those in Comparative Examples 10 and 11 cannot be used in a high temperature environment.

### Example 19

A heat-resistant light-shading film was prepared using a light-shading layer having a double-layered structure where layer structure, layer thickness and composition were: titanium carbide layer (layer thickness: 200 nm, atomic number ratio C/Ti: 0.8)/silicon carbide layer (layer thickness: 20 nm, atomic number ratio C/Si: 0.5). A titanium carbide layer and a silicon carbide layer were coated sequentially on the both sides of a polyimide film having the same kind, thickness and surface roughness as in Example 1 using the reel-equipped sputtering unit illustrated in FIG. 3.

Film surface temperature in the sputtering time was measured in the same manner as in Example 1. The temperature was 190 to 210° C. Kind, thickness and surface roughness of the polyimide were same to those in Example 1.

Evaluations (optical characteristics and heat resistance) of the resultant heat-resistant light-shading film were carried out by the same procedures and under the same conditions as in Example 1. Structure and characteristics of the resultant heat-resistant light-shading film are summarized in Table 1. It was confirmed that the laminated light-shading layer had a good crystallinity. In addition, analysis of oxygen content (O/Me) in each layer was carried out by an XPS while layer surface was removed by sputtering, and it was found that an atomic number ratio O/Si in the SiC layer was 0.1 and an atomic number ratio O/Ti in the TiC layer was 0.2.

Characteristics such as surface resistance and surface roughness, and optical density and surface gloss in the visible region, which were equivalent to those in Example 1, had been obtained. Maximum reflectance in the visible region was 4%, and decrease in reflectance was remarkable compared with Example 1, where only a titanium carbide layer was used without coating a silicon carbide layer on the surface. This decrease in reflectance was resulted by lamination of the titanium carbide layer and the silicon carbide layer both having different optical constants from each other, which caused an antireflection effect due to optical interference.

In addition, evaluation of adhesiveness for the layer after a heating test at 250° C. for 24 hours showed no warpage or peel-off of layer, and it was found that the layer had heat resistance characteristics equivalent to that in Example 1.

Thus, such heat-resistant light-shading film can be used as a member for liquid crystal projectors such as diaphragm, which is used in a high temperature environment, and is useful, in particular, for members locating near lens of projectors for which low reflectance is required.

### Example 20

Experiments were carried out using niobium carbide, molybdenum carbide, vanadium carbide, tantalum carbide, zirconium carbide or hafnium carbide as a light-shading. layer in the same manner as in the case of titanium carbide in Examples 1 to 9 and Comparative Examples 1 to 4, and the same tendency was observed. It was confirmed that a light-shading film having a superior heat resistance could be realized when an atomic number ratio C/Nb, an atomic number ratio C/Mo, an atomic number ratio C/V, an atomic number ratio C/Ta, an atomic number ratio C/Zr or an atomic number ratio C/Hf was 0.3 or more. Every layer was good in crystallinity, and the layer having a thickness of 400 nm or less showed a sufficient light-shading capacity when oxygen content in the layer was 0.5 or less in atomic number ratio O/Me.

### Example 21

A heat-resistant light-shading film was prepared under the same conditions as in Example 1 except that a heat-resistant resin film was changed to a polyethylene naphthalate (PEN) film having a thickness of 25 μm and film surface temperature in the sputtering time was set at 155 to 158° C. Kind of target material and surface roughness of the film substrate were same to those in Example 1.

Evaluations (optical characteristics and heat resistance) of the resultant heat-resistant light-shading film were carried out by the same procedures and under the same conditions as in Example 1. Film surface temperature in the sputtering time of the titanium carbide layer was measured through the inspection window of quartz glass in the reel-equipped sputtering unit by the infrared radiation thermometer in the same manner as in Example 1. The temperature was 155 to 158° C.

Characteristics, e.g., optical density, reflectance, surface gloss, and the like in the visible region, which were equivalent to those in Example 1, had been obtained. In addition, it was confirmed that surface resistance and an arithmetic average heights Ra were 90 Ω/□ and 0.4 μm, respectively. In addition, it was confirmed by the similar method that the light-shading layer was a layer having a good crystallinity. Carbon content and oxygen content in the light-shading layer were same to those in Example 1.

In addition, as for heat resistance, adhesiveness of the layer was similarly evaluated by carrying out a heating test at 155° C. for 24 hours. As a result, it was found that the layer had equivalent heat resistance characteristics to those in Example 1 without showing warpage or peel-off of layer. Structure and characteristics of the resultant heat-resistant light-shading film are summarized in Table 1.

Thus, such heat-resistant light-shading film can be used as a member for in-vehicle monitors, e.g., fixed diaphragm in lens unit, and the like, which is used at 100 to 155° C.

### Examples 22 and 23

Heat-resistant light-shading films were prepared under the same conditions as in Example 21 except that a heat-resistant resin film was changed to a polyethylene naphthalate (PEN) film having a thickness of 6 μm (Example 22) and 12 μm (Example 23). Kind of target material, surface roughness of the film substrates, sputtering conditions were same to those in Example 1. Composition and thickness of the layer were also same to those in Example 21.

Film surface temperature in the sputtering time of the titanium carbide layer was measured through the inspection window of quartz glass in the reel-equipped sputtering unit by the infrared radiation thermometer in the same manner as in Example 1. The temperature was 155° C. Analyses of carbon contents and oxygen contents in the layers were carried out by the similar method gave about the same results to those in Example 1. It was confirmed that every layer was good in crystallinity.

Evaluations (optical characteristics and heat resistance) of the resultant heat-resistant light-shading films were carried out by the same procedures and under the same conditions to those in Example 1.

Characteristics, e.g., optical density, reflectance and surface gloss in the visible region, and surface resistance, surface roughness, and the like, which were equivalent to those in Example 21, had been obtained.

The same heat resistance test as in Example 21 was carried out, and it was found that these films had equivalent heat resistance to that in Example 21 without showing warpage and peel-off of layer. Structures and characteristics of the resultant heat-resistant light-shading films are summarized in Table 1.

Thus, such heat-resistant light-shading film can be used as a member for in-vehicle monitors, e.g., fixed diaphragm in lens unit, and the like, which is used at 100 to 155° C.

### Comparative Example 12

A heat-resistant light-shading film was prepared under the same conditions as in Example 21 except that a titanium layer not containing carbon, which was prepared using a Ti target, was used as a light-shading film. Kind, thickness and surface roughness of the layer substrate and thickness of the light-shading layer were same to those in Example 21.

Structure and characteristics of the resultant heat-resistant light-shading layer are described in Table 2.

Film surface temperature in the sputtering time of the light-shading film was measured through the inspection window of quartz glass in the reel-equipped sputtering unit by the infrared radiation thermometer in the same manner as in Example 21. The temperature was 155 to 158° C., which was equivalent film temperature to that in Example 21.

Evaluations (optical characteristics and heat resistance) of the resultant heat-resistant light-shading film were carried out by the same procedures and under the same conditions to those in Example 21. As a result, characteristics, e.g., optical density, reflectance, surface gloss, surface resistance, arithmetic average height Ra of the surface, and the like, which were equivalent to those in Example 21, had been obtained. Crystallinity of the light-shading layer was good.

However, evaluation of the layer after a heating test at 155° C. for 24 hours, which was the same heat resistance test conditions to those in Example 21, showed no warpage but did occurrence of layer peel-off and also significant color change due to a change in reflectance. Cross-sectional observation of the layer by a TEM showed that the surface and the interface facing the film substrate of the light-shading layer had been oxidized. This oxidation is thought to be a cause of decrease in adhesiveness and color change of the layer.

Thus, such heat-resistant light-shading film cannot be used as a member for in-vehicle monitors, e.g., fixed diaphragm in lens unit and the like, which is used even at 155° C.

### Comparative Examples 13 to 16

Heat-resistant light-shading films were prepared by the same method and under the same conditions as in Comparative Example 12 except that Al (Comparative Example 13), Cr (Comparative Example 14), Ni (Comparative Example 15) and Nb (Comparative Example 16) were used as a light-shading layer. As a result, characteristics such as optical density, reflectance, surface gloss, surface resistance, arithmetic average height Ra of the surface, and the like, which were equivalent to those in Example 21, had been obtained.

However, evaluation of the layer after a heating test at 155° C. for 24 hours, which was the same heat resistance test conditions to those in Example 21, showed no warpage but did occurrence of layer peel-off and also significant color change due to a change in reflectance. Cross-sectional observation of the layer by a TEM showed that the surface and the interface facing the film substrate of the light-shading layer had been oxidized. This oxidation is thought to be a cause of decrease in adhesiveness and color change of the layer.

Thus, such heat-resistant light-shading film cannot be used as a member for in-vehicle monitors, e.g., fixed diaphragm in lens unit and the like, which is used even at 155° C.

### Example 24

A heat-resistant light-shading film was prepared under the same conditions as in Example 1 except that a polyimide (PI) film having an arithmetic average height Ra of 2.2 μm, which was prepared by surface treatment with sand blasting under different conditions. Kind of target material, type and thickness of the polyimide film were same to those in Example 1.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C., which was equivalent film temperature to that in Example 1. Evaluations (optical characteristics and heat resistance) of the resultant heat-resistant light-shading film were carried out by the same procedures and under the same conditions to those in Example 1.

As a result, characteristics such as optical density, surface gloss, and the like, which were equivalent to those in Example 1, had been obtained. In addition, it was confirmed that surface resistance and an arithmetic average height Ra were 120 Ω/□ and 2.1 μm, respectively. Maximum reflectance in the visible region was 3%. Crystallinity, carbon content and oxygen content of the light-shading layer were equivalent to those in Example 1.

Evaluation of adhesiveness of the layer after a heating test at 250° C. for 24 hours exhibited no warpage or peel-off of layer, demonstrating that the layer had equivalent heat resistance characteristics to that in Example 1. Structure and characteristics of the resultant heat-resistant light-shading film are summarized in Table 1. Regular reflectance in the visible region was 3% at a maximum, indicating that the film is of low reflectivity.

Thus, such heat-resistant light-shading film can be used as a member for liquid crystal projectors such as diaphragm, which is used in a high temperature environment.

### Example 25

A heat-resistant light-shading film was prepared under the same conditions as in Example 1 except that a polyimide (PI) film having an arithmetic average height Ra of 1.6 μm, which was prepared by surface treatment with sand blasting under different conditions. Kind of target material, type and thickness of the polyimide film were same to those in Example 1.

Film surface temperature in the sputtering time of the titanium carbide layer was measured through the inspection window of quartz glass in the reel-equipped sputtering unit by the infrared radiation thermometer in the same manner as in Example 1. The temperature was 200 to 210° C., which was equivalent film temperature to that in Example 1. Evaluations (optical characteristics and heat resistance) of the resultant heat-resistant light-shading film were carried out by the same procedures and under the same conditions to those in Example 1.

As a result, characteristics such as optical density, surface gloss, and the like, which were equivalent to those in Example 1, had been obtained. In addition, it was confirmed that surface resistance and an arithmetic average height Ra were 110 Ω/□ and 1.5 μm, respectively. Maximum reflectance in the visible region was 4%. Crystallinity, carbon content and oxygen content of the light-shading layer were equivalent to those in Example 1.

Evaluation of adhesiveness of the layer after a heating test at 250° C. for 24 hours exhibited no warpage or peel-off of layer, demonstrating that the layers had equivalent heat resistance characteristics to those in Example 1. Structure and characteristics of the resultant heat-resistant light-shading film are summarized in Table 1. Regular reflectance in the visible region was 4% at a maximum, indicating that the film is of low reflectivity.

Thus, such heat-resistant light-shading film can be used as a member for liquid crystal projectors such as diaphragm, which is used in a high temperature environment.

### Example 26

Each of the heat-resistant light-shading films prepared in Examples 1 to 25 was punched to prepare a light-shading blade having a size of 20 mm×30 mm. Weight of one light-shading blade was 0.01 to 0.03 g. The two blades were mounted in a diaphragm device to be tested for durability.

In the durability test, the light-shading blades were moved in a range covering a maximum and minimum opening diameters several tens of thousand times while they were irradiated with light from a lamp to evaluate their heat and wear resistance.

The tested light-shading blades were wear-resistant to show no change in external appearances and no wear-caused foreign matter deposited in the diaphragm device. Therefore, the heat-resistant light-shading blade brings various advantages, e.g., reduced friction, wear and noise, reduced weight resulting from use of the resin film as the substrate, reduced driving torque of the motor which drove them, and improved sliding characteristics.

### Comparative Example 17

Light-shading blades using a stainless steel (SUS) foil plate as the substrate and having a size of 20 mm×30 mm were prepared by punching the SUS foil plate in the same manner as in Example 26 except that the light-shading blade material was replaced with a metallic SUS foil plate. Weight of the light-shading blade was 0.2 to 0.5 g.

The tested blades showed no wear-caused change in external appearance and no wear-caused foreign matter deposited in the diaphragm device. However, the blades needed an increased driving torque of the motor which drove them, due to an increased weight of the light-shading blades, and showed deteriorated sliding characteristics.

### Example 27

A heat-resistant light-shading film having the same structure as in Example 1 was produced under the same production conditions except that the film surface temperature in the sputtering time was changed to 50 to 100° C. Such film surface temperature was obtained by adjusting a temperature of the cooling can in a range from −20 to 20° C. The light-shading layer was a crystalline layer and carbon content and oxygen content in the layer were same to those in Example 1.

The resultant heat-resistant light-shading film was evaluated for heat resistance after a heating test at 250° C. for 24 hours. The layer showed no warpage and no color change due to a change of reflectance, but did occurrence of peel-off of layer. Evaluation after the heating test at 155° C. for 24 hours gave the same results.

However, evaluation after a heating test at 130° C. for 24 hours showed none of warpage, color change of layer and peel-off of layer. For the sample after subjecting to punching, the heating test at 130° C. for 24 hours was carried out, but peel-off of layer in an edge did not occur. Thus, such heat-resistant light-shading film can be used for optical members such as fixed diaphragm of digital still cameras and the like, which are utilized at a comparatively low temperature, e.g., ordinary temperature or 130° C. or lower.

### Example 28

Heat-resistant light-shading films having same structures as in Examples 21 to 23 were produced under the same production conditions except that the film surface temperature in the sputtering time was changed to 50 to 100° C. Such film surface temperature was obtained by adjusting a temperature of the cooling can in a range from −20 to 20° C. The light-shading layers were crystalline layers and carbon content and oxygen content in the layers were same to those in Example 21.

The resultant heat-resistant light-shading films were evaluated for heat resistance after a heating test at 250° C. for 24 hours. The layers showed no warpage and no color change due to a change of reflectance, but did occurrence of peel-off of layer. Evaluation after a heating test at 155° C. for 24 hours gave the same results.

However, evaluation after a heating test at 130° C. for 24 hours showed none of warpage, color change of layer and peel-off of layer. For the samples after subjecting to punching, the heating test at 130° C. for 24 hours was carried out, but peel-off of layer in an edge did not occur. Thus, such heat-resistant light-shading film can be used for optical members such as fixed diaphragm of digital still cameras and the like, which are utilized at a comparatively low temperature, e.g., ordinary temperature or 130° C. or lower.

### Examples 29 to 31

Heat-resistant light-shading films having same structure as in Example 28 were produced under the same production conditions except that the gas pressure in the sputtering time was changed to 0.2 Pa (Example 29), 0.8 Pa (Example 30) and 1.0 Pa (Example 31). The light-shading layers were crystalline layers and carbon content and oxygen content in the layers were same to those in Example 21.

The resultant heat-resistant light-shading films were evaluated after a heating test at 250° C. for 24 hours. The layers showed no warpage and no color change due to a change of reflectance, but did occurrence of peel-off of layer. Evaluation after the heating test at 155° C. for 24 hours gave the same results.

However, evaluation after a heating test at 130° C. for 24 hours showed none of warpage, color change of layer and peel-off of layer. For the samples after subjecting to punching, a heating test at 130° C. was carried out, but peel-off of layer in an edge did not occur. Thus, such heat-resistant light-shading film can be used for optical members such as fixed diaphragm of digital still cameras and the like, which are used at a comparatively low temperature, e.g., ordinary temperature or 130° C. or lower.

### Comparative Examples 18 to 19

Heat-resistant light-shading films having same structure as in Example 28 were produced under the same production conditions except that the gas pressure in the sputtering time was changed to 1.3 Pa (Comparative Example 18) and 1.8 Pa (Comparative Example 19). Each of the light-shading layers was amorphous layer and different from those in Examples 28 to 31. Carbon content and oxygen content in each layer were same to those in Example 21.

For the resultant heat-resistant light-shading films, a heat resistance test was carried out at 130° C. for 24 hours. Both films showed warpage, color change due to a change in reflectance, and significant peel-off of layer.

Evaluations by a heat resistance test at 80° C. for 24 hours or 100° C. for 24 hours gave the same results. Thus, such heat-resistant light-shading film cannot be used even for optical members such as fixed diaphragm of digital still cameras and the like, which are utilized at a comparatively low temperature, e.g., 130° C. or lower.

### Example 32

A heat-resistant light-shading film having same structure as in Examples 11 was produced under the same production conditions to those in Example 11 except that the argon gas pressure in the sputtering time was changed to 1.0 Pa and the film surface temperature in the sputtering time was changed to 50 to 100° C. Such film surface temperature was obtained by adjusting a temperature of the cooling can in a range from −20 to 20° C. The light-shading layer was crystalline layer as illustrated in FIG. 7, and carbon content and oxygen content in the layer were same to those in Example 11.

The resultant heat-resistant light-shading film was evaluated for heat resistance after a heating test at 250° C. for 24 hours. The film showed no warpage and no color change due to a change of reflectance, but did occurrence of peel-off of layer. Evaluation after a heating test at 155° C. for 24 hours gave the same results.

However, evaluation after a heating test at 130° C. for 24 hours showed none of warpage, color change of layer and peel-off of layer. For the sample after subjecting to punching, a heating test at 130° C. was carried out, but peel-off of layer in an edge did not occur. Thus, such heat-resistant light-shading film can be used for optical members such as fixed diaphragm of digital still cameras and the like, which are utilized at a comparatively low temperature, e.g., ordinary temperature or 130° C. or lower.

### Comparative Example 20

A heat-resistant light-shading film having same structure as in Example 32 was produced under the same production conditions except that the gas pressure in the sputtering time was changed to 1.5 Pa. Carbon content and oxygen content in the layer were same to those in Example 11. For the light-shading layer, X-ray diffraction measurement was carried out. No diffraction peak was observed, indicating that the layer was amorphous layer and different from those in Example 11 and Example 32.

For the resultant heat-resistant light-shading films, a heat resistance test was carried out at 130° C. for 24 hours. The film showed warpage, color change due to a change in reflectance, and significant peel-off of layer.

Evaluations by a heat resistance test at 80° C. for 24 hours or 100° C. for 24 hours gave the same results. Thus, such heat-resistant light-shading film cannot be used even for optical members such as fixed diaphragm of digital still cameras and the like, which are utilized at a comparatively low temperature, e.g., 130° C. or lower.

### Comparative Example 21

A heat-resistant light-shading film having same structure as in Example 1 was prepared under the same conditions as in Example 11 except that the gas pressure in the sputtering time was changed to 1.5 Pa. Type, thickness and surface roughness of polyimide film and thickness of tungsten carbide layer were same to those in Example 11.

Film surface temperature in the sputtering time of the titanium carbide layer was measured through the inspection window of quartz glass in the reel-equipped sputtering unit by the infrared radiation thermometer in the same manner as in Example 1. The temperature was 185 to 195° C., which was equivalent to the film temperature in Example 11.

Evaluation (optical characteristics and heat resistance) of the resultant heat-resistant light-shading film was carried out by the same procedures and under the same conditions as in Example 1. As a result, characteristics, e.g., optical density, reflectance, surface gloss., and the like, which were equivalent to those in Example 1, had been obtained. In addition, it was confirmed that surface resistance and arithmetic average height Ra of the surface were 105 Ω/□ and 0.4 μm, respectively. Carbon content and oxygen content in the layer were same to those in Example 11. However, in X-ray diffraction measurement of the light-shading layer, no diffraction peak was observed, indicating that the layer had an amorphous structure.

Evaluation of the layer after a heating test at 250° C. for 24 hours showed no warpage but did occurrence of peel-off of layer, and significant color change due to a change in reflectance. Cross-sectional observation of the layer by a TEM showed that the surface and the interface facing the polyimide of the light-shading layer were oxidized. The oxidation is thought to be a cause of decrease in adhesiveness and occurrence of color change.

Thus, such heat-resistant light-shading film cannot be used as members for liquid crystal projectors, e.g., diaphragm, and the like, which are used in a high temperature environment.

TABLE 1

| | | | | | | | | | Characteristics of light-shading film | | | | | | |
|---|---|---|---|---|---|---|---|---|---|---|---|---|---|---|---|
| | | | | | | | | | Surface | | Optical | Maximum | | | |
| | Resin film | | | | | | | Film surface | roughness | | density | reflectance | | | |
| | | | Surface | | | | Coated side | temperature | Ra of | | in the | in the | | | |
| | | | Roughness | Light-shading layer | | | One side/ | in | coated | Surface | visible | visible | | Friction | |
| | Type | Thickness | Ra | Composition | Composition | Thickness | Both sides | sputtering | surface | resistance | region | region | Heat resistance | coefficient | Remarks |
| Example 1 | PI | 75 μm | 0.5 μm | Ti—C | C/Ti = 0.8 | 200 nm | Both sides | 200-210° C. | 0.4 μM | 98 Ω/□ | 4 or more | 7% | ◯ | 0.3 or | |
| | | | | | | | | | | | | | | less | |
| Example 2 | PI | 75 μm | 0.5 μm | Ti—C | C/Ti = 0.8 | 110 nm | Both sides | 180-200° C. | 0.4 μM | 190 Ω/□ | 4 or more | 7% | ◯ | 0.3 or | |
| | | | | | | | | | | | | | | less | |
| Example 3 | PI | 75 μm | 0.5 μm | Ti—C | C/Ti = 0.8 | 550 nm | Both sides | 180-200° C. | 0.3 μM | 80 Ω/□ | 4 or more | 7% | ◯ | 0.3 or | |
| | | | | | | | | | | | | | | less | |
| Example 4 | PI | 75 μm | 0.2 μm | Ti—C | C/Ti = 0.8 | 200 nm | Both sides | 200-210° C. | 0.1 μM | 105 Ω/□ | 4 or more | 10% | ◯ | 0.3 or | |
| | | | | | | | | | | | | | | less | |
| Example 5 | PI | 75 μm | 0.8 μm | Ti—C | C/Ti = 0.8 | 200 nm | Both sides | 200-210° C. | 0.7 μM | 90 Ω/□ | 4 or more | 7% | ◯ | 0.3 or | |
| | | | | | | | | | | | | | | less | |
| Example 6 | PI | 75 μm | 0.5 μm | Ti—C | C/Ti = 0.3 | 200 nm | Both sides | 200-210° C. | 0.4 μM | 90 Ω/□ | 4 or more | 7% | ◯ | 0.3 or | |
| | | | | | | | | | | | | | | less | |
| Example 7 | PI | 75 μm | 0.5 μm | Ti—C | C/Ti = 0.5 | 200 nm | Both sides | 200-210° C. | 0.4 μM | 92 Ω/□ | 4 or more | 7% | ◯ | 0.3 or | |
| | | | | | | | | | | | | | | less | |
| Example 8 | PI | 75 μm | 0.5 μm | Ti—C | C/Ti = 1.1 | 200 nm | Both sides | 200-210° C. | 0.4 μM | 115 Ω/□ | 4 or more | 7% | ◯ | 0.3 or | |
| | | | | | | | | | | | | | | less | |
| Example 9 | PI | 200 μm | 0.5 μm | Ti—C | C/Ti = 0.8 | 200 nm | One side | 270-310° C. | 0.4 μM | 95 Ω/□ | 4 or more | 7% | ◯ | 0.3 or | Floating |
| | | | | | | | | | | | | | | less | method |
| Example 10 | PI | 50 μm | 0.5 μm | W—C | C/W = 0.3 | 150 nm | Both sides | 190-203° C. | 0.4 μM | 95 Ω/□ | 4 or more | 6% | ◯ | 0.3 or | |
| | | | | | | | | | | | | | | less | |
| Example 11 | PI | 50 μm | 0.5 μm | W—C | C/W = 0.6 | 150 nm | Both sides | 190-203° C. | 0.4 μM | 96 Ω/□ | 4 or more | 6% | ◯ | 0.3 or | |
| | | | | | | | | | | | | | | less | |
| Example 12 | PI | 50 μm | 0.5 μm | W—C | C/W = 0.9 | 150 nm | Both sides | 190-203° C. | 0.4 μM | 123 Ω/□ | 4 or more | 6% | ◯ | 0.3 or | |
| | | | | | | | | | | | | | | less | |
| Example 13 | PI | 125 μm | 0.4 μm | Si—C | C/Si = 0.35 | 270 nm | Both sides | 205-213° C. | 0.3 μM | 105 Ω/□ | 4 or more | 6% | ◯ | 0.3 or | |
| | | | | | | | | | | | | | | less | |
| Example 14 | PI | 125 μm | 0.4 μm | Si—C | C/Si = 0.5 | 270 nm | Both sides | 205-213° C. | 0.3 μM | 121 Ω/□ | 4 or more | 6% | ◯ | 0.3 or | |
| | | | | | | | | | | | | | | less | |
| Example 15 | PI | 125 μm | 0.4 μm | Si—C | C/Si = 0.95 | 270 nm | Both sides | 205-213° C. | 0.3 μM | 156 Ω/□ | 4 or more | 6% | ◯ | 0.3 or | |
| | | | | | | | | | | | | | | less | |
| Example 16 | PI | 20 μm | 0.6 μm | Al—C | C/Al = 0.3 | 230 nm | Both sides | 200-210° C. | 0.5 μM | 100 Ω/□ | 4 or more | 5% | ◯ | 0.3 or | |
| | | | | | | | | | | | | | | less | |
| Example 17 | PI | 20 μm | 0.6 μm | Al—C | C/Al = 0.7 | 230 nm | Both sides | 200-210° C. | 0.5 μM | 112 Ω/□ | 4 or more | 5% | ◯ | 0.3 or | |
| | | | | | | | | | | | | | | less | |
| Example 18 | PI | 20 μm | 0.6 μm | Al—C | C/Al = 1.0 | 230 nm | Both sides | 200-210° C. | 0.5 μM | 125 Ω/□ | 4 or more | 5% | ◯ | 0.3 or | |
| | | | | | | | | | | | | | | less | |
| Example 19 | PI | 75 μm | 0.5 μm | Ti—C | C/Ti = 0.8 | 200 nm | Both sides | 190-210° C. | 0.4 μM | 100 Ω/□ | 4 or more | 4% | ◯ | 0.3 or | |
| | | | | Si—C | C/Si = 0.5 | 20 nm | | | | | | | | less | |
| Example 21 | PEN | 25 μm | 0.5 μm | Ti—C | C/Ti = 0.8 | 200 nm | Both sides | 155-158° C. | 0.4 μM | 90 Ω/□ | 4 or more | 5% | ◯ | 0.3 or | |
| | | | | | | | | | | | | | | less | |
| Example 22 | PEN | 6 μm | 0.5 μm | Ti—C | C/Ti = 0.8 | 200 nm | Both sides | 155-158° C. | 0.4 μM | 88 Ω/□ | 4 or more | 4% | ◯ | 0.3 or | |
| | | | | | | | | | | | | | | less | |
| Example 23 | PEN | 12 μm | 0.5 μm | Ti—C | C/Ti = 0.7 | 200 nm | Both sides | 155-158° C. | 0.4 μM | 92 Ω/□ | 4 or more | 5% | ◯ | 0.3 or | |
| | | | | | | | | | | | | | | less | |
| Example 24 | PI | 75 μm | 2.2 μm | Ti—C | C/Ti = 0.8 | 200 nm | Both sides | 200-210° C. | 2.1 μM | 120 Ω/□ | 4 or more | 3% | ◯ | 0.3 or | |
| | | | | | | | | | | | | | | less | |
| Example 25 | PI | 75 μm | 1.6 μm | Ti—C | C/Ti = 0.8 | 200 nm | Both sides | 200-210° C. | 1.5 μM | 110 Ω/□ | 4 or more | 4% | ◯ | 0.3 or | |
| | | | | | | | | | | | | | | less | |

TABLE 2

| | | | | | | | Coated | |
|---|---|---|---|---|---|---|---|---|
| | | | | | | | side | Film |
| | Resin film | | | | | | One | surface |
| | | | Surface | | | | side/ | temperature |
| | | | Roughness | Light-shading layer | | | Both | in |
| | Type | Thickness | Ra | Composition | Composition | Thickness | sides | sputtering |
| Comparative | PI | 75 μm | 0.5 μm | Ti—C | C/Ti = 0.8 | 90 nm | Both | 180-200° C. |
| Example 1 | | | | | | | sides | |
| Comparative | PI | 75 μm | 0.1 μm | Ti—C | C/Ti = 0.8 | 200 nm | Both | 200-210° C. |
| Example 2 | | | | | | | sides | |
| Comparative | PI | 75 μm | 2.3 μm | Ti—C | C/Ti = 0.8 | 110 nm | Both | 200-210° C. |
| Example 3 | | | | | | | sides | |
| Comparative | PI | 75 μm | 0.5 μm | Ti—C | C/Ti = 0.15 | 200 nm | Both | 200-210° C. |
| Example 4 | | | | | | | sides | |
| Comparative | PI | 75 μm | 0.5 μm | Ti | C/Ti = 0 | 200 nm | Both | 200-210° C. |
| Example 5 | | | | | | | sides | |
| Comparative | PI | 50 μm | 0.5 μm | W—C | C/W = 0.1 | 150 nm | Both | 190-203° C. |
| Example 6 | | | | | | | sides | |
| Comparative | PI | 50 μm | 0.5 μm | W | C/W = 0 | 150 nm | Both | 190-203° C. |
| Example 7 | | | | | | | sides | |
| Comparative | PI | 125 μm | 0.4 μm | Si—C | C/Si = 0.2 | 270 nm | Both | 205-213° C. |
| Example 8 | | | | | | | sides | |
| Comparative | PI | 125 μm | 0.4 μm | Si | C/Si = 0 | 270 nm | Both | 205-213° C. |
| Example 9 | | | | | | | sides | |
| Comparative | PI | 20 μm | 0.6 μm | Al—C | C/Al = 0.1 | 230 nm | Both | 200-210° C. |
| Example 10 | | | | | | | sides | |
| Comparative | PI | 20 μm | 0.6 μm | Al | C/Al = 0 | 230 nm | Both | 200-210° C. |
| Example 11 | | | | | | | sides | |
| Comparative | PEN | 25 μm | 0.5 μm | Ti | C/Ti = 0 | 200 nm | Both | 155-158° C. |
| Example 12 | | | | | | | sides | |

| | Characteristics of light-shading film | | | | | | |
|---|---|---|---|---|---|---|---|
| | Surface | | Optical | Maximum | | | |
| | roughness | | density in | reflectance | | | |
| | Ra of | | the | in the | | | |
| | coated | Surface | visible | visible | Heat | Friction | |
| | surface | resistance | region | region | resistance | coefficient | Remarks |
| Comparative | 0.4 μm | 300 Ω/□ | 3.0 | 6% | ◯ | 0.3 or | |
| Example 1 | | | | | | less | |
| Comparative | 0.05 μm | 110 Ω/□ | 4 or more | 33% | ◯ | 0.3 or | |
| Example 2 | | | | | | less | |
| Comparative | 2.2 μm | 86 Ω/□ | 2.0 | 3% | ◯ | 0.3 or | |
| Example 3 | | | | | | less | |
| Comparative | 0.4 μm | 86 Ω/□ | 4 or more | 6% | X | 0.3 or | |
| Example 4 | | | | | | less | |
| Comparative | 0.4 μm | 86 Ω/□ | 4 or more | 6% | X | 0.3 or | |
| Example 5 | | | | | | less | |
| Comparative | 0.4 μm | 91 Ω/□ | 4 or more | 6% | X | 0.3 or | |
| Example 6 | | | | | | less | |
| Comparative | 0.4 μm | 83 Ω/□ | 4 or more | 6% | X | 0.3 or | |
| Example 7 | | | | | | less | |
| Comparative | 0.3 μm | 98 Ω/□ | 4 or more | 6% | X | 0.3 or | |
| Example 8 | | | | | | less | |
| Comparative | 0.3 μm | 91 Ω/□ | 4 or more | 6% | X | 0.3 or | |
| Example 9 | | | | | | less | |
| Comparative | 0.5 μm | 92 Ω/□ | 4 or more | 5% | X | 0.3 or | |
| Example 10 | | | | | | less | |
| Comparative | 0.5 μm | 82 Ω/□ | 4 or more | 5% | X | 0.3 or | |
| Example 11 | | | | | | less | |
| Comparative | 0.4 μm | 90 Ω/□ | 4 or more | 5% | X | 0.3 or | |
| Example 12 | | | | | | less | |

1. A heat-resistant light-shading film comprising a resin film substrate (A) having a heat resistance of 155° C. or higher and a light-shading layer (B) of crystalline metal carbide layer (MeC) formed on one side or both sides of the resin film substrate (A), characterized in that the light-shading layer (B) has a thickness of 100 nm or more and a surface roughness of 0.1 to 2.1 μm (arithmetic average height Ra), and content of carbon element (C) in the metal carbide layer (MeC) is 0.3 or more in atomic number ratio (C/Me) to the total metal elements (Me).

2. The heat-resistant light-shading film according to claim 1, characterized in that the resin film substrate (A) is composed of at least one kind of material selected from polyethylene naphthalate, polyimide, aramid, polyphenylene sulfide or polyether sulfone.

3. The heat-resistant light-shading film according to claim 1, characterized in that heat resistance of the resin film substrate (A) is 200° C. or higher.

4. The heat-resistant light-shading film according to claim 1, characterized in that thickness of the resin film substrate (A) is 5 to 200 μm.

5. The heat-resistant light-shading film according to claim 1, characterized in that surface roughness of the resin film substrate (A) is 0.2 to 2.2 μm (arithmetic average height Ra).

6. The heat-resistant light-shading film according to claim 1, characterized in that thickness of the light-shading layer (B) is 110 to 550 nm.

7. The heat-resistant light-shading film according to claim 1, characterized in that the metal carbide layer (MeC) comprises, as a main component, at least one kind of material selected from silicon carbide, titanium carbide, aluminum carbide, niobium carbide, tungsten carbide, molybdenum carbide, vanadium carbide, tantalum carbide, zirconium carbide or hafnium carbide.

8. The heat-resistant light-shading film according to claim 1, characterized in that content of carbon element (C) in the metal carbide layer (MeC) is 0.5 or more in atomic number ratio (C/Me) of carbon element (C) to the total metal elements (Me).

9. The heat-resistant light-shading film according to claim 1, characterized in that content of oxygen (O) in the metal carbide layer (MeC) is 0.5 or less in atomic number ratio (O/Me) of oxygen element (O) to the total metal elements (Me).

10. The heat-resistant light-shading film according to claim 1, characterized in that reflectance of the light-shading layer (B) for the light in a wavelength range from 380 to 780 nm is 10% or less.

11. The heat-resistant light-shading film according to claim 1, characterized in that optical density as an index of light-shading capacity is 4 or more in a wavelength range from 380 to 780 nm.

12. The heat-resistant light-shading film according to claim 1, characterized in that metal carbide layers (MeC) having the same structure and thickness are formed on the both sides of the resin film substrate (A).

13. A method for producing a heat-resistant light-shading film comprising a resin film substrate (A) having a heat resistance of 155° C. or higher and a metal carbide layer (MeC) as a light-shading layer (B) formed on one side or both sides of the resin film substrate (A), characterized by comprising steps for supplying the resin film substrate (A) having a surface roughness of 0.2 to 2.2 μm (arithmetic average height Ra) to a sputtering unit; and for forming a crystalline metal carbide layer (MeC) having a thickness of 100 nm or more, a surface roughness of 0.1 to 2.1 μm (arithmetic average height Ra), and a content of carbon element (C) in the metal carbide layer (MeC) of 0.3 or more in atomic number ratio (C/Me) to the total metal elements (Me), on said resin film substrate (A) by the sputtering method using a metal carbide target in an inert gas atmosphere.

14. The method for producing the heat-resistant light-shading film according to claim 13, characterized by comprising steps for supplying further a heat-resistant light-shading film with a metal carbide layer (MeC) formed thereon to a sputtering unit; and forming a metal carbide layer (MeC) on the other side of the resin film substrate (A) on which the metal carbide layer (MeC) has not been formed, by the sputtering method.

15. The method for producing the heat-resistant light-shading film according to claim 13, characterized in that sputtering gas pressure in the period of forming the light-shading layer (B) is 0.2 to 1.0 Pa.

16. The method for producing the heat-resistant light-shading film according to claim 13, characterized in that surface temperature of the resin film substrate (A) in the period of forming the light-shading layer (B) is 180° C. or higher.

17. The method for producing the heat-resistant light-shading film according to claim 13, characterized by comprising steps for setting the resin film substrate (A) in a rolled form in a film transfer section of the sputtering unit; and for forming a layer by the sputtering method while the resin film substrate (A) is running from a wind-off section to a take-up section.

18. The method for producing the heat-resistant light-shading film according to claim 13, characterized by comprising steps for setting the resin film substrate (A) in a rolled form in a film transfer section of the sputtering unit; and for forming a layer by the sputtering method while the resin film substrate (A) is running from a wind-off section to a take-up section, wherein the layer is formed while the resin film substrate (A) is not cooled and in a floating state in a film-forming chamber in the sputtering time.

19. A diaphragm having superior heat resistance obtained by processing the heat-resistant light-shading film according to claim 1.

20. A light intensity adjusting device using the heat-resistant light-shading film according to claim 1.
